(19) United States
(12) Patent Application Publication
(10) Pub. No.: US 2026/0279723 A1
(43) Pub. Date: Sep. 17, 2026

(54) MULTI-BEAM CHARGED PARTICLE MICROSCOPE DESIGN WITH IMPROVED DETECTION SYSTEM FOR SECONDARY ELECTRON IMAGING OVER A LARGE RANGE OF LANDING ENERGIES OF PRIMARY ELECTRONS

(71) Applicant: Carl Zeiss MultiSEM GmbH, Oberkochen (DE)

(72) Inventors: Felix MENKE, Oberkochen (DE); Michael BEHNKE, Eislingen (DE); Kai BITTNER, Erbach (DE); Markus KOCH, Neu-Ulm (DE); Thomas SCHMID, Aalen (DE); Stefan SCHUBERT, Oberkochen (DE); Arne THOMA, Heidenheim (DE); Dirk ZEIDLER, Oberkochen (DE)

(21) Appl. No.: 19/683,724

(22) Filed: May 21, 2026

Related U.S. Application Data
(63) Continuation of application No. PCT/EP2024/025316, filed on Nov. 6, 2024.

(30) Foreign Application Priority Data
Nov. 23, 2023 (DE) 10 2023 211 672.3

(51) Int. Cl. H01J 37/28; H01J 37/145; H01J 37/147; H01J 37/244; H01J 37/26

(52) U.S. Cl. CPC H01J 37/28; H01J 37/147; H01J 37/244; H01J 37/265; H01J 37/145; H01J 2237/2806

(57) ABSTRACT

A multi-beam charged particle system comprises a secondary electron imaging system configured for a compensation of imaging or pupil aberrations over a large range of landing energies of primary charged particles. A method operates the multi-beam charged particle system. The disclosed system and methods can allow for a systematic approach to compensation of imaging or pupil aberrations of a secondary electron imaging system is enabled. The disclosure can be applied, for example, to wafer inspection with a multi-beam charged particle system.

### CROSS-REFERENCE TO RELATED APPLICATIONS

The present application is a continuation of, and claims benefit under 35 USC 120 to, international application No. PCT/EP2024/025316, filed Nov. 6, 2024, which claims benefit under 35 USC 119 of German Application No. 10 2023 211 672.3, filed Nov. 23, 2023. The entire disclosure of each of these applications is incorporated by reference herein.

### FIELD

The disclosure relates to a multi-beam charged particle microscope with an imaging system for imaging secondary electrons onto a detector and a method of operating a multi-beam charged particle microscope.

### BACKGROUND

WO 2005/024881 A2 discloses an electron microscope system which operates with a multiplicity of electron beamlets for the parallel scanning of an object to be inspected with a bundle of electron beamlets. The bundle of primary charged particle beamlets is generated by directing a primary charged particle beam onto a multi-beam forming unit, comprising at least one multi-aperture plate, which has a multiplicity of openings. One portion of the electrons of the electron beam is incident onto the multi-aperture plate and is absorbed there, and another portion of the beam transmits the plurality of openings of the multi-aperture plate. Thereby, in the beam path downstream of each opening, electron beamlets are formed whose cross section is defined by the cross section of the corresponding openings. The plurality of primary charged particle beamlets are focused by an objective lens on a surface of a sample. Secondary electrons or backscattered electrons emanate from the interaction volumes of the plurality of focus points of the plurality of primary charged particle beamlets with the sample. Thereby, a plurality of secondary electron beamlets is emitted from the sample, which is collected and imaged onto a detector. Each of the secondary beamlets is incident onto a separate detector element or group of detector elements, so that the secondary electron intensities detected therewith provide information relating to the surface of the sample at the location where the corresponding primary beamlet is incident onto the sample. The bundle of primary beamlets is scanned systematically over the surface of the sample and an electron microscopic image of the sample is generated.

Generally, the imaging contrast of the multi-beam scanning electron microscope depends on the signal generated by secondary electrons. The signal generally depends on the secondary electron (SE) yield per primary electron and a geometrical collection efficiency of the electron microscope. The SE yield generally depends on material characteristics and the kinetic energy of the primary electrons. The secondary electron beamlets collected by the objective lens are then guided to a detector by a secondary electron imaging system. The imaging performance of the secondary electron imaging system is relevant to the imaging contrast. For example, the secondary electron imaging system forms a plurality of focus points of the secondary electron beamlets on a detector plane. Spot aberrations of distortion may cause crosstalk between the signals corresponding to individual secondary electron beamlets and may therefore cause a reduced signal contrast.

The signal and the resolution of a multi-beam scanning electron microscope can also be dependent on a landing energy of the primary electrons. With lower landing energies, higher resolution can be achieved in some examples. Typically, the landing energy of primary electrons is adjusted depending on an inspection task, for example depending on a combination of materials to be inspected or a charging property of a sample. With different landing energies adjusted between a range of for example 100V to 2 kV or even more, also the kinetic energy of secondary electrons can drastically change.

Different mechanisms have been proposed to improve an imaging contrast of a multi-beam electron microscope. U.S. Pat. Nos. 11,049,686, 10,896,800, 10,811,215 and WO 2021/239380 propose an arrangement of several active electrostatic or magneto-dynamic elements within a secondary electron imaging system. However, these systems do not describe the proper selection and adjustment of the active electrostatic or magneto-dynamic elements.

Generally, elements for focus adjustment, image magnification and image rotation within a secondary electron imaging systems are known. For example, U.S. Pat. Nos. 9,368,314, 7,601,972, 7,049,585, 6,992,290, US 2009/014649, or U.S. Pat. No. 8,362,425, mention zoom lenses and rotation compensators in secondary electron imaging systems. However, certain known systems, such as US 2016/0268096, provide simplified sketches of secondary electron imaging systems. The examples of these references provide a raw conception of a secondary electron imaging system, which is not reduced to a practical design. An expert can be left to use trial and error to design a secondary electron imaging system.

DE 102018124219 A1 and DE102022131862 A1 provide certain background information.

### SUMMARY

Relatively high demands are sometimes set to the performance of the secondary electron imaging system. A secondary electron imaging system with reduced crosstalk is desirable. A secondary electron imaging system with reduced aberrations is desirable. An improved secondary electron imaging system with reduced aberrations over a large of kinetic energies of secondary electrons is desirable.

It is desirable to provide proper guidance regarding how to arrange elements and how many of these elements are used to achieve a desired performance of a secondary electron imaging system.

The disclosure provides a multi-beam charged particle system and a method of operating a multi-beam charged particle system for image acquisition with higher image contrast.

With a multi-beam charged particle beam system according to the disclosure and a method of operating a multi-beam charged particle beam system according to the disclosure, it is possible to provide an aberration compensation within a secondary electron beam path for a relatively large range of kinetic energies of secondary electrons. The relatively large range of kinetic energies of secondary electrons can be correlated to the relatively large range of landing energies LE of primary charged particle. The landing energy LE of primary charged particles is typically varied over a large range of landing energies according to an inspection task. With the landing energy, for example a resolution of an imaging task or a charging behavior at a sample is adjusted. Different inspection tasks at semiconductor wafers can involve different landing energies, and kinetic energies of secondary electrons can vary accordingly. The proper selection of a position of at least a first compensator can be relevant for compensating an electro-optical element responsible for an aberration. Aberrations of a multi-beam secondary electron imaging system typically have a specific dependency on a field coordinate of the image plane. Such aberrations can therefore be described by aberration vector components, which typically can be given by polynomial terms with low order terms comprising for example constant aberrations such as axial astigmatism, pupil anamorphism (i.e. different pupil magnification in x and y), field anamorphism (i.e. different field magnification in x and y), quadratic field distortion (i.e. distortion with a quadratic dependency of field coordinate in x or y), linear field astigmatism (i.e. astigmatism with linear dependency on field coordinate in x or y). The disclosure is however not limited to these aberrations vector components. The disclosure can be applied to other aberrations vector components.

Typically, aberrations are introduced by a specific element of a secondary electron imaging system with a specific signature of aberration vector components and can only be compensated by a compensator of similar signature of aberration vector components. According to an example of the disclosure, this is achieved by placing the compensator at a position within the secondary electron beam path with a similar ratio SAR of a diameter of a single secondary electron beamlet to a diameter of the plurality of secondary electron beamlets. The secondary electron beam path can be subject to a kinetic energy of secondary electrons and therefore can depend on the landing energy of the primary electrons. In an example of the disclosure, at least two compensators or stigmators are applied, which are configured to jointly compensate an aberration within as large range of landing energies. Thereby a variation of an aberration vector introduced by a specific electron-optical element can be compensated even if a kinetic energy of secondary electrons is changed according to a change of the landing energy of the primary electrons by a change of a voltage provided to the sample or wafer. In an example, the positions of the compensators are selected according to the different ratios SAR of the electron-optical element over the range of landing energies. With for example a previously determined aberration vector of the electron-optical element responsible for an aberration, a control of the secondary electron imaging system can be allowed during use within the range of landing energies. With for example a previously determined knowledge of an effect of an actuation of a compensator on the aberration vector for a set of landing energies, a control of the secondary electron imaging system can be allowed during use within the range of landing energies.

According to a first aspect, the disclosure provides a multi-beam charged particle beam system comprising an object irradiation unit configured to form a plurality of focus points of a plurality of primary charged particle beamlets in an object plane. The multi-beam charged particle beam system further comprises a sample stage, configured to arrange a surface of an object in the object plane and a voltage supply unit for providing a voltage VS to the sample configured for setting a first landing energy LE1 of primary charged particles of the plurality of primary charged particle beamlets. The multi-beam charged particle beam system further comprises a detection unit. The detection unit forms at least a part of a secondary electron imaging system, which is configured for imaging a plurality of secondary electron beamlets, which are excited at the surface of the object at the plurality of focus points, along a secondary electron beam path onto a detector. The multi-beam charged particle beam system further comprises a beam divider for separating the plurality of primary charged particle beamlets from the plurality of secondary electron beamlets. The multi-beam charged particle beam system further comprises at least a first electron-optical element, arranged within the secondary electron imaging system at a first position with a first ratio SAR1 of a beam diameter of a single secondary electron beamlet relative to the diameter of the plurality of secondary electron beamlets at the first landing energy LE1 and a first compensator of aberrations introduced by the first electron-optical element. The first compensator is arranged within the secondary electron imaging system at a second position with a second ratio SAR2 at the first landing energy LE1, wherein the second ratio SAR2 is identical to the first ratio SAR1 or deviating from the first ratio SAR1 by not more than 0.1.

The kinetic energy of the secondary electrons generally depends on the selected landing energy LE1 of primary electrons. The secondary electron beam path within the secondary electron imaging system generally depends on the kinetic energy of the secondary electrons and is therefore also depending on the selected landing energy LE1 of the primary electrons. The aberration introduced by a first electron-optical element generally depends on the ratio SAR of a beam diameter of a single secondary electron beamlet relative to the diameter of the plurality of secondary electron beamlets at the position of the first electron-optical element. The ratio SAR can be different for each landing energy or kinetic energy of secondary electrons. The aberration introduced by the first electron-optical element can therefore be different for each landing energy. According to the disclosure, at least a first compensator can be arranged at a position within the secondary electron beam path with a ratio SAR similar to the ration SAR of the first electron-optical element at the selected landing energy LE. Similar means a maximum deviation of 0.1.

In an example, the first electron-optical element is at least a part of the beam divider. A beam divider can have separated components, including for example a component within the primary as well as the secondary electron beam path, and a component solely within the secondary electron beam path. A part of the beam divider is typically an element which breaks the rotational symmetry of the secondary electron beam path. At least a part of the beam divider can therefore be responsible for certain image and pupil aberrations of a specific dependency on a field coordinate.

In an example, at least the first compensator or stigmator is a multi-pole element. Such a multi-pole element can comprise a plurality of electrodes or coils arranged around a beam path for forming in inhomogeneous field distribution within the compensator. The number of electrodes or coils can be at least four, six, eight or even more, for example twelve. Thereby, a variety of inhomogeneous field distributions can be adjusted. In an example, the inhomogeneous field distributions enabled by a compensator are described by an orthogonal set of inhomogeneous field distributions, for example described by polynomial expansion similar to the Zernike polynomial expansion. A compensator is however not limited to multi-pole element, but can for example be configured a electron-optical lens elements configured to be displaced or tilted within the secondary electron beam path.

In an example, the detection unit further comprises an aperture stop arranged at a pupil plane of the secondary electron beam path at the first selected landing energy LE1. The aperture stop can be responsible for an equal filtering of the pupil or angular intensity distributions of each of the plurality of secondary electron beamlets.

In an example, the multi-beam charged particle beam system further comprises a second compensator of aberrations within the secondary electron imaging system. In an example, the second compensator is arranged within the secondary electron imaging system at a third position with a third ratio SAR3 at the first selected landing energy LE1, wherein the third ratio SAR3 is different to the second ratio SAR2 at the position of the first compensator. Thereby, two compensators can be provided with different ratios SAR2 and SAR3, which have therefore a different effect on an imaging aberration of the secondary electron imaging system at the first selected landing energy LE1. In an example, the first compensator and the second compensator are configured to jointly compensate an aberration of the first electron-optical element at the first landing energy LE1. In an example, the first compensator and the second compensator are further configured to jointly compensate an aberration of the first electron-optical element at a second landing energy LE2 or primary charged particles, with the second landing energy LE2 being different from the first landing energy LE1. For a different, second landing energy LE2, the ratios SAR1, SAR2 and SAR3 for each of the first electron-optical element, the first and second compensator are different from the ratios SAR1, SAR2 and SAR3 at the first landing energy LE1. However, with proper selection of position of the first compensators with a ratio SAR2 at least similar to ratio SAR1 of the first electron-optical element at the first landing energy LE1 and selection of position of the second compensator with a ratio SAR3 at least similar to ratio SAR1 of the first electron-optical element at the second landing energy LE2, a compensation of aberrations is enabled for a large range of landing energies LE.

In an example, the secondary electron beam path within the secondary electron imaging system further comprises an intermediate image plane at the first landing energy LE1. The first compensator can be arranged—with respect to a propagation direction of secondary electrons—upstream of the intermediate image plane and the second compensator is arranged downstream of the intermediate image plane. In an alternative example, the first compensator is arranged—with respect to a propagation direction of secondary electrons—upstream of the aperture stop and the second compensator is arranged downstream of the aperture stop within the secondary electron imaging system.

In an example, the multi-beam charged particle beam system further comprises at least one correction lens within the secondary electron imaging system, configured to adjust the pupil plane at a position of the aperture stop at a second landing energy LE2 different from the first landing energy LE1. A pupil plane is defined as a cross over plane and its position within the secondary electron beam path is generally depending on the kinetic energy of secondary electrons or, respectively, the landing energy LE of primary electrons. With the correction lens, the pupil plane can be adjusted at the position of the aperture stop irrespective of the selected second landing energy LE.

According to a second aspect, the disclosure provides a multi-beam charged particle beam system comprising an object irradiation unit configured to form a plurality of focus points of a plurality of primary charged particle beamlets in an object plane. The multi-beam charged particle beam system further comprises a sample stage, configured to arrange a surface of an object in the object plane. The multi-beam charged particle beam system further comprises a voltage supply unit for providing a voltage VS to the sample configured for adjusting a landing energy LE of primary charged particles of the plurality of primary charged particle beamlets within a range between 100 eV or less and 2 keV or more. The multi-beam charged particle beam system further comprises a detection unit, which is forming at least a part of a secondary electron imaging system for imaging a plurality of secondary electron beamlets from the surface of the object onto a detector. Secondary electrons are excited at the surface of the object at the plurality of focus points and are accelerated to kinetic energy which is depending on the selected landing energy LE. The multi-beam charged particle beam system further comprises a beam divider for separating the plurality of primary charged particle beamlets from the plurality of secondary electron beamlets. The multi-beam charged particle beam system further comprises a first compensator and a second compensator configured to jointly compensate an aberration of an electron-optical element of the secondary electron imaging system within a range of kinetic energies of secondary electrons of the plurality of secondary electron beamlets, corresponding to the range of the landing energy LE of the primary charged particles. For example, an aberration is introduced by a part of the beam divider.

In an example, the multi-beam charged particle beam system further comprises an aperture stop and at least one correction lens within the secondary electron imaging system. The correction lens can be configured to adjust a pupil plane at a position of the aperture stop for each landing energy within the range of landing energies LE of primary charged particles beamlets.

In an example, the secondary electron beam path through the secondary electron imaging system comprises between the object plane and an image plane, where the detector is arranged, in this order a first pupil plane, an intermediate image plane and a second pupil plane.

In an example, the first compensator is arranged in the secondary electron beam path between the first pupil plane and the intermediate image plane, and the second compensator is arranged in the secondary electron beam path between the intermediate image plane and the second pupil plane. In an example, the secondary electron imaging system further comprises a third compensator. The third compensator can be arranged between the second pupil plane and the image plane of the secondary electron imaging system.

In another example, the first compensator is arranged in the secondary electron beam path between the first pupil plane and the second pupil plane, and the second compensator is arranged between the second pupil plane and the image plane of the secondary electron imaging system.

In an example, the multi-beam charged particle beam system comprises a first electron-optical element, arranged within the secondary electron imaging system at a first position with a first ratio SAR1 of a beam diameter of a single secondary electron beamlet relative to the diameter of the plurality of secondary electron beamlets at a first landing energy LE1. At least one of the first compensator or the second compensator can be arranged within the secondary electron imaging system at a second position with a second ratio SAR2 at the first landing energy LE1, wherein the second ratio SAR2 can be identical to the first ratio SAR1 or can deviate from the first ratio SAR1 by not more than 0.1. In an example, at least one of the compensators is a multi-pole element or stigmator.

According to a third aspect, the disclosure provides a method of operating a multi-beam charged particle beam system. The method comprises a step of positioning an inspection site on a wafer by a wafer stage in the field of view of a multi-beam charged particle beam system and a step of adjusting a selected landing energy LES of primary electrons within a range of landing energies by a providing a sample voltage VS to the wafer by a voltage supply unit. The method further comprises a step of determining at least a first sensitivity matrix S(LES; 1) of the at least first compensator with f=1 for the selected landing energy LES. The method comprises determining an aberration of a secondary electron imaging system at the selected landing energy LES and determining a first actuation of the at least first compensator at the selected landing energy LES for compensating the aberration. The method further comprises applying the first actuation of the at least first compensator and performing the inspection task. Thereby, a compensation of an aberration is achieved, and an inspection task is performed with high imaging contrast.

In an example, the determining of the aberration comprises describing the aberration by an aberration vector WR(LES). The aberration vector WR(LES) can comprise at least two preselected aberration vector components selected from a group of normalized aberration vector components including axial astigmatism, pupil anamorphism, field anamorphism, quadratic field distortion, linear field astigmatism. Thereby, for example, at least a part of an aberration of a part of a beam divider can be described.

In an example, the method comprises determining a second sensitivity matrix S(LES; f=2) of a second compensator with f=2 for the selected landing energy LES and determining a second actuation of the second compensator at the selected landing energy LES.

In an example, the step of determining the first actuation and the second actuation of the at least first and second compensators comprises determining at least one actuation amplitude C(n,f) of a plurality of normalized actuation modes M(n) for each compensator.

In an example, the step of determining the first actuation and the second actuation of the at least first and second compensators comprises performing an optimization of a matrix equation

∥WR(LES)−Σ_{n,f}G(n;f)*C(n;f)*S(k,n;LES;f)∥²−>min

with aberration vector WR(LES), actuation amplitude C(n,f) of the plurality of normalized actuation modes M(n) for each compensator, sensitivity matrices S(LES; f) for each compensator with index f, and a set of predetermined first weighting functions G(n,f).

In an example, the step of determining the first actuation and the second actuation of the at least first and second compensators comprises performing an optimization of a matrix equation including a minimization of actuation amplitudes C(n,f) of the plurality of normalized actuation modes M(n) for each compensator. In an example, the optimization of the matrix equation is written as

∥WR(LES)−Σ_{n,f}G(n,f)*C(n,f)*S(k,n;LES;f)∥²+∥T(n;f)*C(n;f)∥²−>min

with aberration vector WR(LES), actuation amplitude C(n,f) of the plurality of normalized actuation modes M(n) for each compensator, sensitivity matrices S(LES; f) for each compensator, a set of predetermined first weighting functions G(n,f), and a second set of predetermined second weighting functions T(n,f).

In an example, the values of the first weighting functions G(n,f) are all set to one.

In an example, the first weighting function G(n, 1) is set to a value G(n, 1)>1 for a first compensator with f=1 for a first selected landing energy LES1 and is set to G(n,1)=0 for a second landing energy LES2.

In an example, the step of determining a sensitivity matrix S(LES; f) of a compensator comprises determining the sensitivity matrix S(LES; f) from a set of previously determined sensitivity matrices S(LE(q); f) of the compensator received from a memory. The previously determined sensitivity matrices S(LE(q); f) are for example determined at a set of different landing energies LE(q=1 . . . . Q). In an example, a sensitivity matrix S(LES; f) of a compensator is interpolated from previously determined sensitivity matrices S(LE(q); f) for at least two different landing energies LE(q1) and LE(q2) by interpolation.

In an example, the method further comprises a step of determining the aberration of the secondary electron imaging system at the selected landing energy LES by using a monitoring system. In an example, the aberration of the secondary electron imaging system at the selected landing energy LES is determined from at least two previously determined aberration vectors WR(Le(q)) received from a memory.

In a fourth aspect, the disclosure provides a method of calibrating of a compensator of a secondary electron imaging system is provided. The method allows for a calibration of a compensator of a multi-beam charged particle beam system within a range of landing energies LE is. The method comprises a step of determining a set of N normalized actuation modes M(n=1 . . . . N) of the compensator. Normalized actuation modes M(n) can for example be derived from a Zernike polynomial expansion. The method further comprises a step of determining an aberration vector WR of the secondary electron imaging system, wherein the aberration vector WR comprises at least K=2 normalized aberration vector components selected from a group of normalized aberration vector components including axial astigmatism, pupil anamorphism, field anamorphism, quadratic field distortion, linear field astigmatism.

The method further comprises a step of individually applying each normalized actuation mode M(n) with an actuation amplitude C(n) at the compensator (264) and a step of adjusting a first landing energy LE(1) from a set of landing energies LE(q) and determining a change of an aberration vector dW at the first landing energy LE(1) induced by applying an actuation mode M(n) to the compensator. The method comprises a step of repeating adjusting the landing energy and determining a change of an aberration dW for each landing energy LE(q)=(2 . . . . Q) of the set of landing energies and each normalized actuation mode M(n). The method further comprises the step of determining a normalized sensitivity matrix S(k=1 . . . . K,n=1 . . . . N,LE(q)) of K normalized aberration vector components of each normalized actuation mode M(n=1 . . . . N) for each of the landing energies LE(q), and storing the plurality of sensitivity matrices S(k=1 . . . . K,n=1 . . . . N,LE(q)) in a memory for later use during performance of an inspection task.

In an example, the step of determining an aberration vector WR comprises the at least K=2 normalized aberration vector components of the secondary electron imaging system at each landing energy LE(q)=(2 . . . . Q) of the set of landing energies by using a monitoring system without actuation of a compensator.

According to a fifth aspect, the disclosure provides a multi-beam charged particle beam system, which comprises an object irradiation unit configured to form a plurality of focus points of a plurality of primary charged particle beamlets in an object plane, and a sample stage, configured to arrange a surface of an object in the object plane. The multi-beam charged particle beam system further comprises a voltage supply unit for providing a voltage VS to the sample configured for setting a selected landing energy LES of primary charged particles of the plurality of primary charged particle beamlets within a range of landing energies LE. The multi-beam charged particle beam system further comprises a detection unit forming at least a part of a secondary electron imaging system for imaging a plurality of secondary electron beamlets, which are excited at the surface of the object at the plurality of focus points, along a secondary electron beam path onto a detector. The multi-beam charged particle beam system further comprises a beam divider for separating the plurality of primary charged particle beamlets from the plurality of secondary electron beamlets and at least a first compensator of aberrations of the secondary electron imaging system. The multi-beam charged particle beam system further comprises a control unit comprising control operation processor and a memory for storing software instructions. When executed by the control operation processor, the software instructions are causing the multi-beam charged particle beam system to perform any of the method steps described above.

In an example, the multi-beam charged particle beam system further comprises a second compensator of aberrations arranged within the secondary electron imaging system. In an example, the multi-beam charged particle beam system further comprises a third compensator of aberrations arranged within the secondary electron imaging system.

The disclosure provides a multi-beam charged particle beam system and a method of operating a multi-beam charged particle beam system, which can exhibit improved image contrast. The disclosure can allow a wafer inspection, including charging wafer samples, with higher precision and with a higher accuracy.

It will be understood that the disclosure is not limited to the embodiments and examples but comprises also combinations and variations of the embodiments and examples.

### BRIEF DESCRIPTION OF THE DRAWINGS

Embodiments of the present disclosure will be explained in more detail with reference to drawings, in which:

FIG. 1 is a schematic sectional view of a multi-beam charged particle beam system;

FIG. 2 illustrates some details of a multi-beam charged particle beam system;

FIG. 3 illustrates a detector with an optical relay system;

FIGS. 4A-4B illustrate a known secondary electron imaging system;

FIGS. 5A-5C illustrate a first example of an improved secondary electron imaging system;

FIGS. 6A-6C illustrate a second example of an improved secondary electron imaging system;

FIGS. 7A-7C illustrate a third example of an improved secondary electron imaging system;

FIGS. 8A-8B illustrate a fourth example of an improved secondary electron imaging system;

FIGS. 9A-9B illustrate a sub-aperture ratio SAR;

FIG. 10 illustrates a fifth example of an improved secondary electron imaging system;

FIG. 11 illustrates a method of determining aberration vector components of a secondary electron imaging system;

FIG. 12 illustrates a method of calibration of stigmators of a secondary electron imaging system;

FIGS. 13A-13F illustrate examples of low order actuation modes of a stigmator;

FIGS. 14A-14B illustrate further examples of actuation modes of a stigmator; and

FIG. 15 illustrates a method of operation of a multi-beam charged particle beam system.

### DESCRIPTION OF EXEMPLARY EMBODIMENTS

In the exemplary embodiments of the disclosure described below, components similar in function and structure are indicated as far as possible by similar or identical reference numerals.

Some array elements, for example the plurality of primary charged particle beamlets, are identified by a reference number. Depending on the context, the same reference number may also identify a single element out or the array elements. Each primary charged particle beamlet (3.1, 3.2, 3.3) is one beamlet of the plurality of primary charged particle beamlets (3).

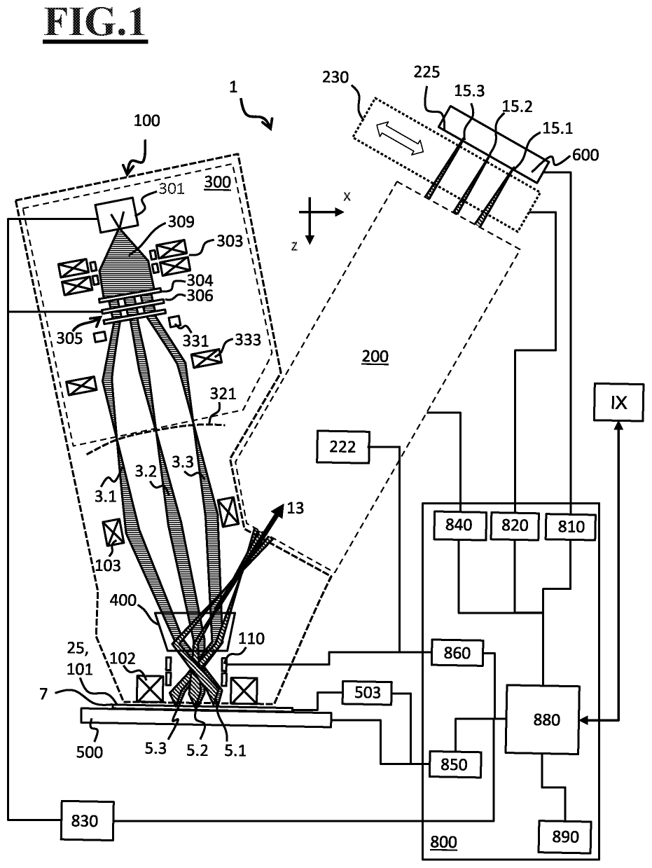

The schematic representation of FIG. 1 illustrates basic features and functions of a multi-beam charged-particle system 1. It is to be noted that the symbols used in the figure have been chosen to symbolize their respective functionality. The type of system shown is that of a multi-beam scanning electron microscope using a plurality of primary charged particle beamlets 3 for generating a plurality of primary charged particle beam spots 5 on a surface 25 of an object 7, such as a wafer or mask substrate located with a top surface 25 in an object plane 101 of an objective lens 102. For simplicity, only three primary charged particle beamlets 3.1 to 3.3 and three primary charged particle beam spots 5.1 to 5.3 are shown. The features and functions of multi-beamlet charged-particle system 1 can be implemented using electrons or other types of primary charged particles such as ions, such as Helium ions. Further details of the microscope system 1 are provided in International Patent application WO 2022/262970 A1, which is hereby fully incorporated by reference.

The system 1 comprises an object irradiation unit 100 and a detection unit 200 and a secondary electron beam divider or beam splitter unit 400 for separating the secondary charged-particle beam path 13 from the primary charged-particle beam path 11. The object irradiation unit 100 comprises a charged-particle multi-beam generator 300 for generating the plurality of primary charged-particle beamlets 3 and is adapted to focus the plurality of primary charged-particle beamlets 3 in the object plane 101, in which the surface 25 of an object or wafer 7 is positioned by a sample stage 500.

The primary beam generator 300 produces a plurality of primary charged particle beamlet spots in an intermediate image surface 321. The primary beamlet generator 300 comprises at least one source 301 of primary charged particles, for example electrons. The at least one primary charged particle source 301 emits a diverging primary charged particle beam, which is collimated by at least one collimating lens 303 to form a collimated or parallel primary charged particle beam 309. The collimating lens 303 is usually consisting of one or more electrostatic or magnetic lenses, or by a combination of electrostatic and magnetic lenses. The collimated primary charged particle beam 309 is incident on the primary multi-beam forming unit 305. A multi-beam generating unit 305 is for example explained in US 2019/0259575, and in U.S. Pat. No. 10,741,355 B1, both hereby incorporated by reference. The multi-beam forming unit 305 basically comprises a first multi-aperture plate or filter plate 304 illuminated by the collimated primary charged particle beam 309. The first multi-aperture plate or filter plate 304 comprises a plurality of apertures in a raster configuration for generation of the plurality of primary charged particle beamlets 3, which are generated by transmission of the collimated primary charged particle beam 309 through the plurality of apertures. The multi-beamlet forming unit 305 comprises at least one further multi-aperture plate 306, which is located, with respect to the direction of movement of the electrons in beam 309, downstream of the first multi-aperture or filter plate 304. For example, a second multi-aperture plate 306 comprises for example four or eight of electrostatic elements for each of the plurality of apertures, for example to deflect each of the plurality of beamlets individually. The multi-beamlet forming unit 305 is further configured with an adjacent electrostatic field lens 331, which is in some examples combined in the multi-beamlet forming unit 305. Together with a second field lens 333, each of the plurality of primary charged particle beamlets 3 is focused in or in proximity of the intermediate image surface 321. The primary charged-particle source 301 and each of the active multi-aperture plates 306 are controlled by control unit 830.

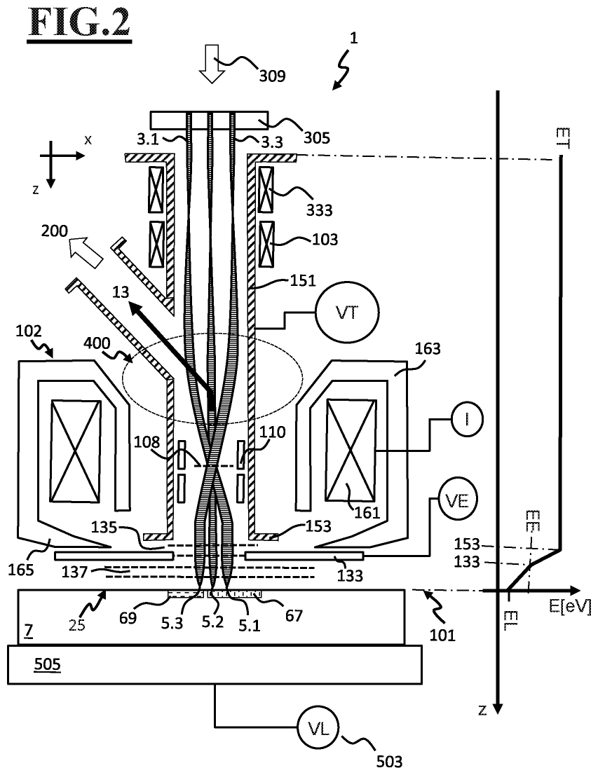

The plurality of focus points of primary charged particle beamlets 3 passing the intermediate image surface 321 is imaged by field lens group 103 and objective lens 102 into the object plane 101, in which the surface 25 of the object 7 is positioned. A decelerating electrostatic field is generated between the objective lens 102 and the object surface 25 by application of a voltage to the object by the sample voltage supply 503. With the decelerating electrostatic field generated by sample voltage supply 503, a landing energy EL of primary electrons is adjusted to for example below 2 keV, 1 keV, below 800 eV, below 500 eV, below 300 eV or even less, for example 100 eV. FIG. 2 illustrates further details of the decelerating electrostatic field generated. From a collimated electron beam 309, a plurality of primary charged particle beamlets 3 is generated by the multi-aperture arrangement 305. For simplicity, only 3 beamlets 3.1 to 3.3 are shown, but there can be more beamlets, for example more than 60, more than 90, or even more than 300 beamlets. A beam tube 151 is provided downstream of the multi-aperture arrangement 305, the beam tube 151 being connected to a voltage supply with the first or tube voltage VT. From the entrance of a beam tube 151, the plurality of primary charged particle beamlets 3 is at a constant kinetic energy ET until the exit opening 153 of the beam tube 151. The kinetic energy ET of the primary charged particle beamlets 3 during passing the beam tube 151 is for example 20 keV, 30 keV or more.

The plurality of primary charged particle beamlets 3 are imaged and focus points 5.1 to 5.3 are formed in an image plane 101 by field lenses 333 and 103, and by objective lens 102. The objective lens 102 is of the type of a magnetic lens with a coil 161 and a pole shoe 163 with a lower pole shoe segment 165, forming an axial gap for the magnetic field. A current I is provided during use to the coil 161 to generate the focusing magnetic field (not shown). Other types of magnetic lenses are possible as well, for example radial gap lenses for generation an immersion lens field, or magnetic lenses with several coils and pole shoes. Upstream or partially integrated in the objective lens 102, a beam divider 400 is arranged, configured to separate the secondary electrons along secondary electron beam path 13 to detector unit 200. Below the lower pole shoe segment 165, an electrode 133 is provided, connected to a voltage supply for providing a second voltage VE to the electrode. In the example shown, the electrode 133 is provided as separate electrode. The voltage difference between VT and VE is responsible for the generation of a first electric field 135, illustrated in FIG. 2 with the equipotential lines of the first electric field 135. The first electrical field vectors are almost parallel to the propagation direction of the primary charged particle beamlets 3 and generate a decelerating force to the primary charged particles. Via sample voltage supple 503, a sample voltage VL is provided by sample voltage supply 503 to a sample mounting platform 505 for holding and contacting during use a wafer 7. According to the voltage difference between VL and VE, a second electrical field 137 is generated, which is almost parallel to the propagation direction of the primary charged particle beamlets 3 and generates a decelerating force to the primary charged particles. The third or sample voltage VL is adjusted such that the third kinetic energy or landing energy EL of the primary electrons is adjusted in a range below 2 keV, 1 keV, 800 eV, below 300 eV or even below 100 eV. At the surface 25 of the wafer 7, a first material composition 67 is arranged under a first set of primary charged particle beamlets 3.1 and 3.2, and a second material composition 69 is arranged under a second set of primary charged particle beamlet comprising primary charged particle beamlet 3.3. The electrical fields 135 and 137 both form a decelerating field to reduce the kinetic energy of the primary charged particle beamlets 3 before impinging on the sample surface 25 arranged in the image plane 101, such that a high resolution is achieved. The first electrical field 135 also forms an accelerating field on secondary electrons extracted from the wafer 7. The second electrical field 137 forms an extraction field for extracting and accelerating secondary electrons from the wafer 7. The second field 137 is therefore also called the extraction field 137.

The example illustrated in FIG. 2 shows a multi-beam charged particle beam system 1 with a two-stage deceleration field 135 and 137 and an additional electrode 133. In another example only a single decelerating or extraction field 137 is generated between exit aperture 153 of the beam tube 151 and a sample 7 mounted on the sample platform 505. In this case, the exit aperture 153 of the beam tube 151 has the role of the electrode 133 for the extraction field 137.

The object irradiation system 100 of the multi-beam charged particle beam system 1 shown in FIGS. 1 and 2 further comprises a collective multi-beam raster scanner 110 in proximity of a beam cross over 108 by which the plurality of charged particle beamlets 3 can be deflected in scanning direction 143 perpendicular to the propagation direction of the charged particle beamlets. The propagation direction of the primary beamlets throughout the examples is in positive z-direction. Objective lens 102 and collective multi-beam raster scanner 110 are centered at an optical axis (not shown) of the multi-beam charged-particle system 1, which is perpendicular to wafer surface 25. The plurality of primary charged particle beamlets 3, forming the plurality of beam spots 5 arranged in a raster configuration, is scanned synchronously over the wafer surface 25. In an example, the raster configuration of the focus spots 5 of the plurality of J primary charged particle 3 is a hexagonal raster of about one hundred or more primary charged particle beamlets 3, for example J=91, J=100, or J approximately 300 or more beamlets. The primary beam spots 5 have a distance about 6 μm to 45 μm and a diameter of below 5 nm, for example 3 nm, 2 nm or even below. In an example, the beam spot size is about 3 nm, and the distance between two adjacent beam spots is 8 μm. At each scan position of each of the plurality of primary beam spots 5, a plurality of secondary electrons is generated, respectively, forming the plurality of secondary electron beamlets in the same raster configuration as the primary beam spots 5. The intensity of secondary charged particle beamlets generated at each beam spot 5 depends on the intensity of the impinging primary charged particle beamlet 3, illuminating the corresponding spot 5, the material compositions 67, 69 and topography of the object 7 under the beam spot 5, and the charging condition of the sample at the beam spot 5. The plurality of secondary charged particle beamlets are accelerated by the same electrostatic field between objective lens 102 and object surface 25 and are collected by objective lens 102 and pass the first collective multi-beam raster scanner 110 in opposite direction to the primary beamlets 3. The plurality of secondary beamlets is scanning deflected by the first collective multi-beam raster scanner 110. The plurality of secondary charged particle beamlets is then guided by the beam splitter unit 400 to follow the secondary beam path 13 to the detection unit 200. The plurality of secondary electron beamlets is travelling in opposite direction from the primary charged particle beamlets 3 with kinetic energy ES=ET−EL, and the beam splitter unit 400 is configured to separate the secondary beam path 11 from the primary beam path usually via magnetic fields or a combination of magnetic and electrostatic fields.

Detection unit 200 images the secondary electron beamlets onto the image sensor 600 to form there a plurality of secondary charged particle image spots 15. The detector or image sensor 600 comprises a plurality of detector pixels or individual detectors. For each of the plurality of secondary charged particle beam spots 15, the intensity is detected separately, and the property of the object surface 25 is detected with high resolution for a large image patch of the object 7 with high throughput. For example, with a raster of 10×10 beamlets with 8 μm pitch, an image patch of approximately 88 μm×88 μm is generated with one image scan with collective multi-beam raster scanner 110, with an image resolution of for example 2 nm or below. The image patch is sampled with half of the beam spot size, thus with a pixel number of 8000 pixels per image line for each beamlet, such that the image patch generated by 100 beamlets comprises 6.4 gigapixel. The digital image data is collected by control unit 800. Details of the digital image data collection and processing, using for example parallel processing, are described in international patent application WO 2020/151904 A2 and in U.S. Pat. No. 9,536,702, which are hereby incorporated by reference.

Detection unit 200 further comprises at least a second raster scanner 222, which is connected to scanning control unit 860. Scanning control unit 860 is configured to compensate a difference in the scanning deflection power of the first scanning deflector 110 in the common beam path, such that the positions of the plurality secondary electron focus spots 15 are kept constant at image sensor 600. The difference in the scanning deflection power of the first scanning deflector 110 arises from the difference between the kinetic energy ET of primary electrons with respect to the kinetic energy ES of secondary electrons. The system 1 may further comprise an optionally retractable monitoring system 230. Monitoring systems and monitoring methods to detect charging effects at such charging samples are further described in patent applications WO 2022/248141 A1 and DE 102022114923.4, which are hereby fully incorporated by reference. The detection unit 200 is described in more detail below.

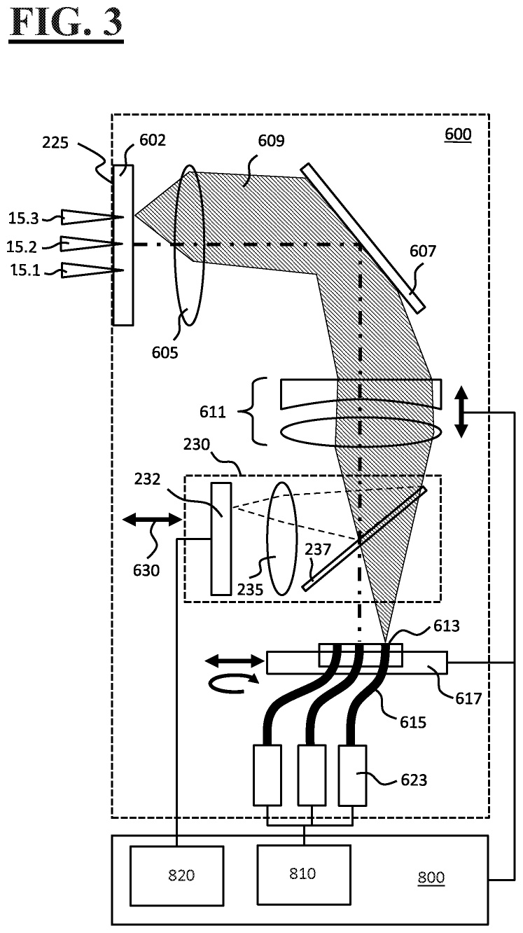

The image sensor 600 is configured by an array of sensing areas in a pattern compatible to the raster arrangement of the secondary electron beamlets focused by the detection unit 200 onto the image sensor 600. This enables a detection of each individual secondary electron beamlet independent from the other secondary electron beamlets incident on the image sensor 600. The image sensor 600 illustrated in FIG. 1 can be an electron sensitive detector array such as a CMOS or a CCD sensor. Such an electron sensitive detector array can comprise an electron to photon conversion unit, such as a scintillator element or an array of scintillator elements. In another embodiment, the image sensor 600 can be configured as electron to photon conversion unit or scintillator plate arranged in the focal plane of the plurality of secondary electron particle image spots 15. An example is shown in FIG. 3. The image sensor 600 can further comprise a relay optical system comprising collection lenses 605 and zoom lens 611 for imaging and guiding the photons generated by the electron to photon conversion unit 602 at the secondary charged particle image spots 15 on dedicated photon detection elements 623, such as a plurality of photomultipliers or avalanche photodiodes. Such an image sensor is disclosed in U.S. Pat. No. 9,536,702, which is cited above and incorporated by reference. The image sensor is further configured with an optionally extractable monitoring system 230, comprising a beam divider mirror 237, an imaging lens 235 and a CMOS sensor 232 with high resolution.

During an acquisition of an image patch by scanning the plurality of primary charged particle beamlets 3, the stage 500 is optionally not moved, and after the acquisition of an image patch, the stage 500 is moved to the next image patch to be acquired. In an alternative implementation, the stage 500 is continuously moved in a second direction while an image is acquired by scanning of the plurality of primary charged particle beamlets 3 with the collective multi-beam raster scanner 110 in a first direction. Stage movement and stage position is monitored and controlled by sensors known in the art, such as Laser interferometers, grating interferometers, confocal micro lens arrays, or similar.

During an image scan, the control unit 800 is configured to trigger the image sensor 600 to detect in predetermined time intervals a plurality of timely resolved intensity signals from the plurality of secondary electron beamlets, and the digital image of an image patch is accumulated and stitched together from all scan positions of the plurality of primary charged particle beamlets 3.

The control unit 800 of the multi-beamlet charged-particle system 1 further comprises an—imaging control module 810, configured to receive the data streams from the image sensor 600 and to generate a digital image of the surface of the sample 7 during operation; a secondary beam-path control module 840, configured to control the detection unit 200; a primary beam-path control module 830, configured to control the elements of the object irradiation unit 100; a stage control module 850, configured to control the stage positioning and alignment, and including control of the sample voltage supply unit 503; a scanning operation control module 860, configured to control a scanning operation by the first collective multi-beam raster scanner 110 and the second deflection system 222; a control operation processor unit 880, configured to execute inspection tasks of samples, and configured to control the modules 810, 820, 830, 840, 850, 860 and a memory 890 for storing software, instructions and image data. The control operation processor unit 880 is further connected to an interface IX for exchange of data, instructions, software or user interaction.

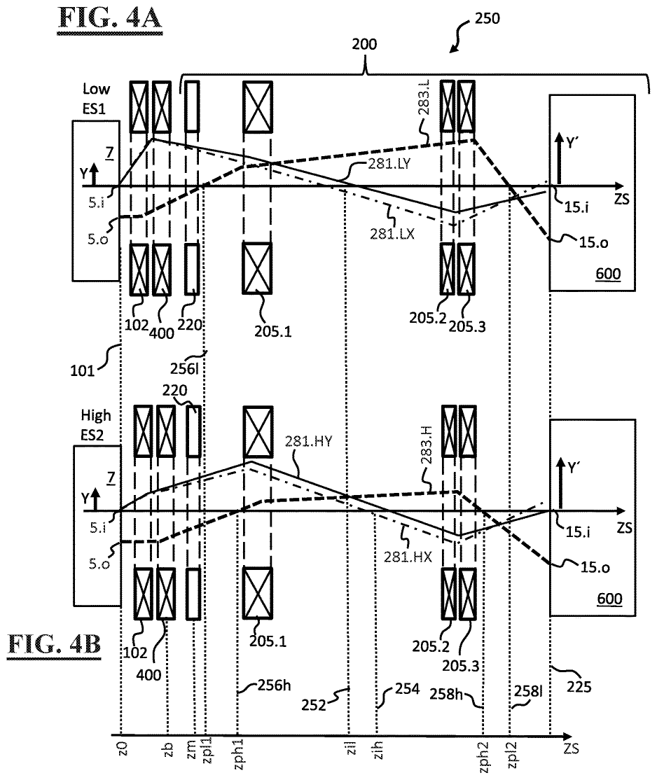

FIGS. 4A-4B illustrate a secondary electron imaging system 250, comprising objective lens 102, beam divider 400 and detection unit 200 according to known technology. Along a propagation axis ZS, following elements are arranged:
the surface 25 of the object 7 in object plane 101 at coordinate zs=0
objective lens 102,
beam divider 400 at coordinate zs=zb,
a stigmator 220 a coordinate zs=zm,
a first electron-optical lens 205.1,
a second and a third electron-optical lens 205.2, 205.3,
the image plane 225 of the detection unit 200, at which the detector 600 is arranged.

FIG. 4A illustrates beam trajectories a low kinetic energy ES of secondary electrons. Trajectory 281 illustrate trajectories of secondary electrons from an axial field point 5.i. Two trajectories 281.LX and 281.LY are shown. The trajectories in x and y are different due to an astigmatism of the secondary electron imaging system 250. A third trajectory 283.L illustrates a trajectory of a secondary electron leaving the sample surface 25 at an off-axis field point 5.o with an angle perpendicular to the wafer surface 25 or object plane 101.

At low kinetic energy ES1, within the secondary electron imaging system 250, a first low-energy cross over or pupil plane 256l is formed at distance zpl1 and a first intermediate image plane 252 is formed at distance zil. Further, a second cross-over or pupil plane 258i is formed at distance zpl2.

FIG. 4B illustrates beam trajectories a high kinetic energy ES of secondary electrons. Corresponding secondary electron trajectories are illustrated with labels 281.HX, 281.HY, and 283.H. At high kinetic energy ES2, within the secondary electron imaging system 250, a first low-energy cross over or pupil plane 256h is formed at distance zph1 and a first intermediate image plane 254 is formed at distance zih. Further, a second cross-over or pupil plane 258h is formed at distance zph2. Typically, each pupil or intermediate field plane 256, 252, 254 and 258 is at different zs-position, depending on the kinetic energy of secondary electrons, i.e. for example, zph2<zpl1, or zil<zih, or zpl1<zph1.

Astigmatism is a wavefront-aberration, corresponding to a formation of two perpendicular elliptical focus points with an axial distance. Field anamorphism is given by a different imaging scale in x- and y-direction of an imaging system. Both aberrations are inherently connected. Both aberrations do not exist in systems of rotational symmetry. However, the secondary electron imaging system 250 comprises beam divider 400, which is responsible for a break of rotational symmetry. The purpose of stigmator 220 is a correction of an axial astigmatism and a field anamorphism. However, it has turned out that stigmator 220 is insufficient to compensate axial astigmatism and field anamorphism for different kinetic energies of secondary electrons. Furthermore, it has turned out that an unproperly placed stigmator 220 introduces aberrations of higher order.

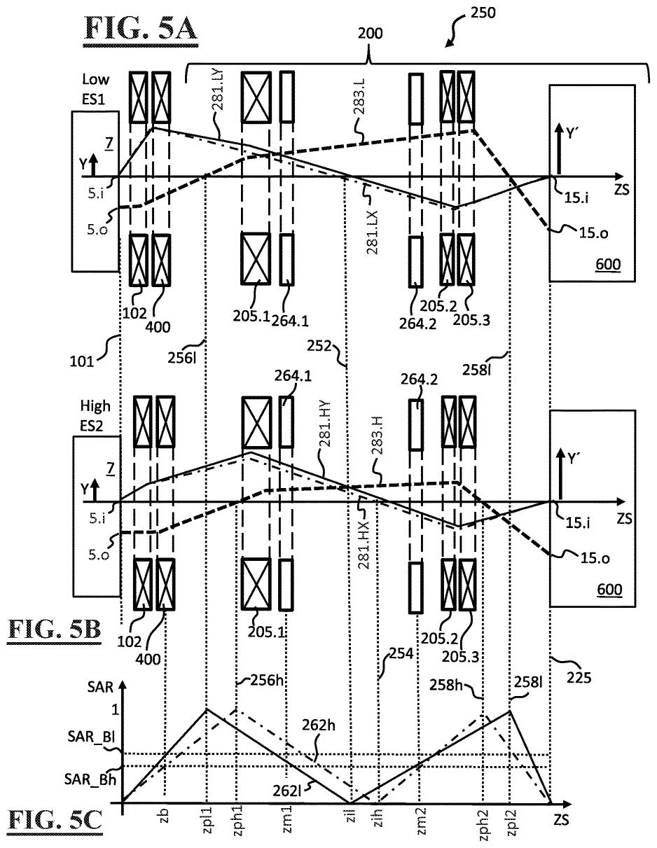

FIGS. 5A-5C illustrate an embodiment of an improved secondary electron imaging system 250. Same reference numbers of FIGS. 4A-4B are used and reference is also made to FIGS. 4A-4B. FIG. 5A illustrates selected secondary electron trajectories 281 and 283 of the improved secondary electron imaging system 250 at a first, low kinetic energy ES1 of secondary electrons. FIG. 5B illustrates selected secondary electron trajectories 281 and 283 of the improved secondary electron imaging system 250 at a second, high kinetic energy ES2 of secondary electrons. Instead of a single stigmator 220 at position zm, a first stigmator 264.1 is inserted at position zm1 and an optically equivalent position to beam divider 400. Beam divider 400 is at position zb. Optical positions within the secondary electron optical system are described by the ratio SAR of an effective diameter of a single secondary electron beamlet to the diameter of the plurality of secondary electron beamlets. This ratio is called sub-aperture ratio SAR, which is illustrated in FIG. 5C. At a field plane 101, 225 or zi, SAR=0; at cross-over or pupil planes zp1, zp2, SAR=1. In between, SAR continuously changes between SAR=0 and SAR=1. In the example of FIGS. 5A-5C, for the low kinetic energy ES1, the SAR_B of beam divider 400 is approximately SAR_B1=0.5, while for the high kinetic energy ES2, the SAR_B of beam divider 400 is approximately SAR_Bh=0.3. An imaging aberration introduced at a position of a specific SAR can only be compensated at a position of identical SAR. In a first example, a first stigmator or compensator 264.1 is arranged within the secondary electron imaging system 250 at a position with SAR approximately equal to SAR_B1. However, given the dependency of SAR_B from the kinetic energy of secondary electrons, it is not possible to compensate axial astigmatism and field anamorphism in parallel for all kinetic energies of secondary electrons. In a second example, a second stigmator or compensator 264.2 is provided (see FIG. 5A or 5B). With the combine actuation of first and second stigmator 264.1 and 264.2, axial astigmatism as well as field anamorphism can be compensated over the desired range of kinetic energies of secondary electrons without the introduction of higher order aberrations. In an example, the second stigmator or compensator 264.2 is arranged within the secondary electron imaging system 250 at a position with SAR approximately equal to SAR_Bh. Thereby, with a combined activation of first and second stigmators 264.1 and 264.2, a compensation of aberrations introduced by the beam divider 400 is even more improved with reduced introduction of higher order aberrations.

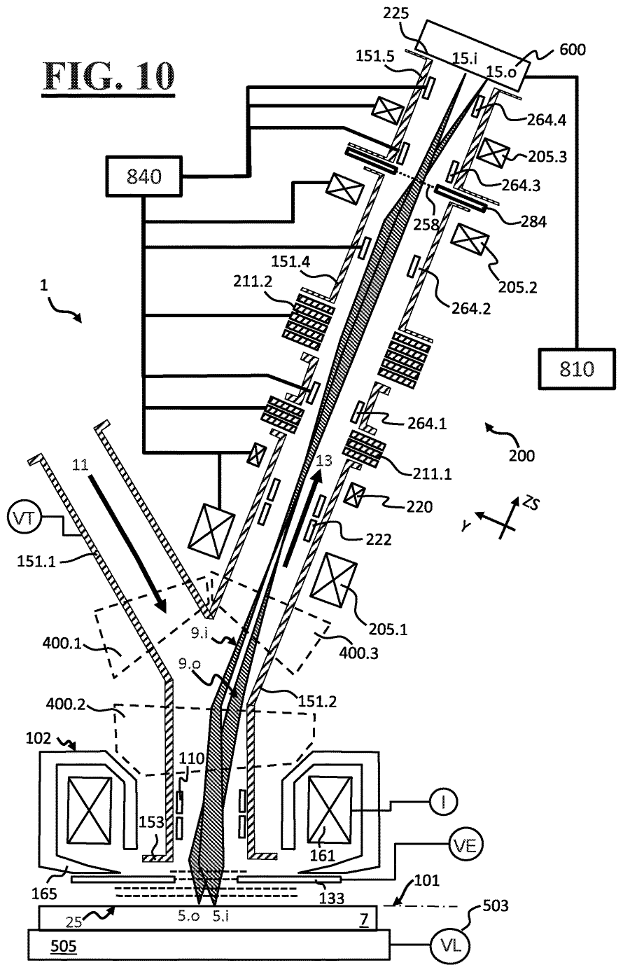

Typically, only a part or a component of the beam divider 400 is responsible for contributing an aberration to the secondary electron beam path. For example, as will be described at the example of FIG. 10 below in more detail, beam divider 400 comprises a beam divider component 400.3 arranged solely within the secondary electron beam path 13. This beam divider component 400.3 may be responsible for an aberration in dependence on a kinetic energy of secondary electrons or the landing energy of primary electrons, respectively.

Generally, according to the first embodiment, a secondary electron imaging system 250 comprises at least a first stigmator 264.1 or 264.2 located at a position with equal sub-aperture ratio SAR of an element, which is responsible for an aberration within the secondary electron imaging system 250, for example beam divider 400 at a position with sub-aperture ratio SAR_B at a first selected kinetic energy of secondary electrons. A first SAR is considered as equal to a second SAR, for example SAR_B, if both SARs show a deviation of 15% or less, for example 10% or 5%. In a multi-beam charged particle beam system 1 configured for imaging a plurality of secondary beamlets 9, a proper selection of a location of a stigmator 264 can be of greater relevance. This can be different in single beam systems, where a compensation of aberrations is typically performed at the single charged particle beam before scanning. On the other hand, within a multi-beam charged particle beam system, an element may introduce an aberration with a specific field dependency for the plurality of charged particle beamlets, for example the plurality of secondary electron beamlets 9; for a compensation of an aberration of an element with a specific field dependency it is optional to select a placement of a stigmator 264 at an optically equivalent position with similar SAR.

In an example, the secondary electron imaging system 250 further comprises a second stigmator 264.2. With the combine actuation of first and second stigmator 264.1 and 264.2, aberrations can be compensated over the desired range of kinetic energies of secondary electrons. In an example, the second stigmator 264.2 is located at a position with equal sub-aperture ratio SAR of an element, which is responsible for an aberration within the secondary electron imaging system 250.

In the example of FIGS. 5A-5C, the secondary electron beam path 13 within the secondary electron imaging system 250 further comprises an intermediate image plane 252 at a low kinetic energy and an intermediate image plane 254 at a high kinetic energy of secondary electrons. The first compensator 264.1 is arranged—with respect to a propagation direction of secondary electrons—upstream of an intermediate image plane 252 or 254 and the second compensator 264.2 is arranged downstream of an intermediate image plane 252 or 254.

During the description, the terms “compensator” and “stigmator” is used. It should be noted that a compensator or stigmator according to the embodiments can be implemented as a conventional stigmator, which conventionally is implemented as a multi-pole element with at least four electrostatic of magnetic poles for generating an inhomogeneous field distribution. Examples are described below. Compensators or stigmators are however not limited to multi-pole elements but can also be implemented for example as electron optical lenses capable of being displaced or tilted with respect to the secondary electron beam path.

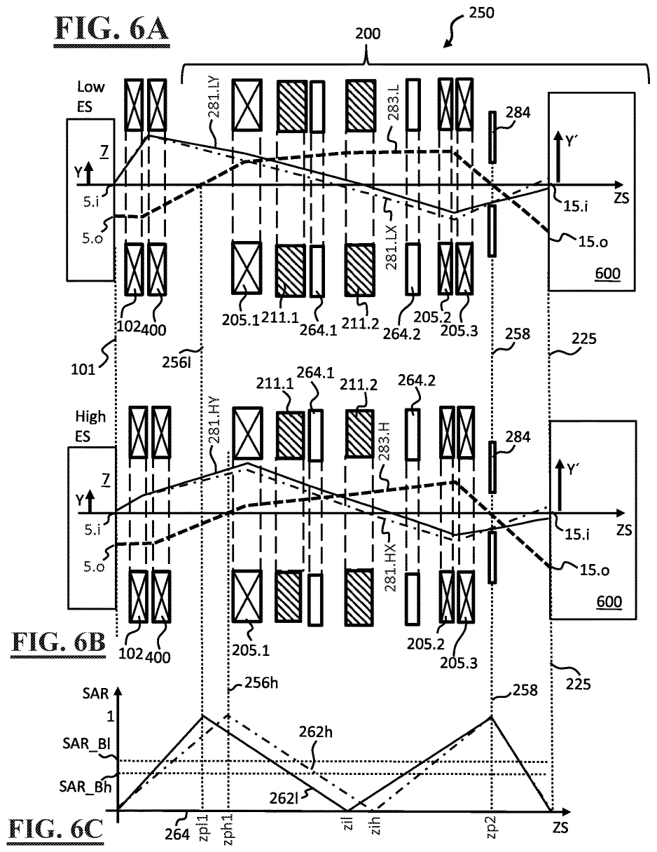

A second embodiment is illustrated in FIGS. 6A-6C. Same reference numbers of FIGS. 4A-4B and 5A-5C are used, and reference is also made to FIGS. 4 and 5. FIG. 6A illustrates selected secondary electron trajectories 281 and 283 of the improved secondary electron imaging system 250 at a first, low kinetic energy ES1 of secondary electrons. FIG. 6B illustrates selected secondary electron trajectories 281 and 283 of the improved secondary electron imaging system 250 at a second, high kinetic energy ES2 of secondary electrons. FIG. 6C illustrates the sub-aperture ratios SAR of the improved secondary electron imaging system 250 for the two selected kinetic energies ES1 and ES2. The secondary electron imaging system 250 according to the third embodiment further comprises an aperture stop 284 at a cross-over or pupil plane 258. With the aperture stop 284, an image contrast is adjusted such that for example each secondary electron beamlet provides a similar or identical image contrast. Such aperture stops are described in PCT/EP2023/025426, filed on Oct. 10, 2023, which is hereby fully incorporated by reference. The pupil position 258, however, is subject to the kinetic energy of the secondary electrons (see FIGS. 5A-5B, pupil plane coordinates at zpl2>zph2). In an example, the secondary electron imaging system 250 according to the second embodiment comprises at least one electron-optical lens element 211.1 or 211.2 upstream of the filter or pupil plane 258. With the at least one electron-optical lens element 211.1 or 211.2, a position zp2 of a pupil plane 258 is maintained at constant position irrespective of a kinetic energy of secondary electrons. In an example, secondary electron imaging system 250 according to the second embodiment comprises at least two electron-optical lens element 211.1 and 211.2.

Axial astigmatism and field anamorphism are interrelated to pupil aberrations, which can introduce an unwanted effect of the filter operation by the aperture stop 284. Pupil aberrations are for example a pupil anamorphism, corresponding to a deformation of a pupil distribution into an elliptical shape. Such pupil aberrations can be different for each field point. Therefore, for example, a filter operation by aperture stop 284 can be different for each of the plurality of secondary electron beamlets 9, generating a different image contrast for different secondary electron beamlets 9 or different field points 5. The improved secondary electron imaging system 250 according to the second embodiment comprises at least a first stigmator 264.1 and a second stigmator 264.2 for compensation of an axial astigmatism, a field anamorphism and a pupil aberration. Such aberrations may be introduced by the beam divider 400 and are at least partially compensated by the first stigmator 264.1 and second stigmator 264.2. In an example, at least one of the compensators or stigmators 264.1 or 264.2 is positioned at a position with a SAR similar to the SAR_B of a component of the beam divider 400 for a selected kinetic energy of secondary electrons.

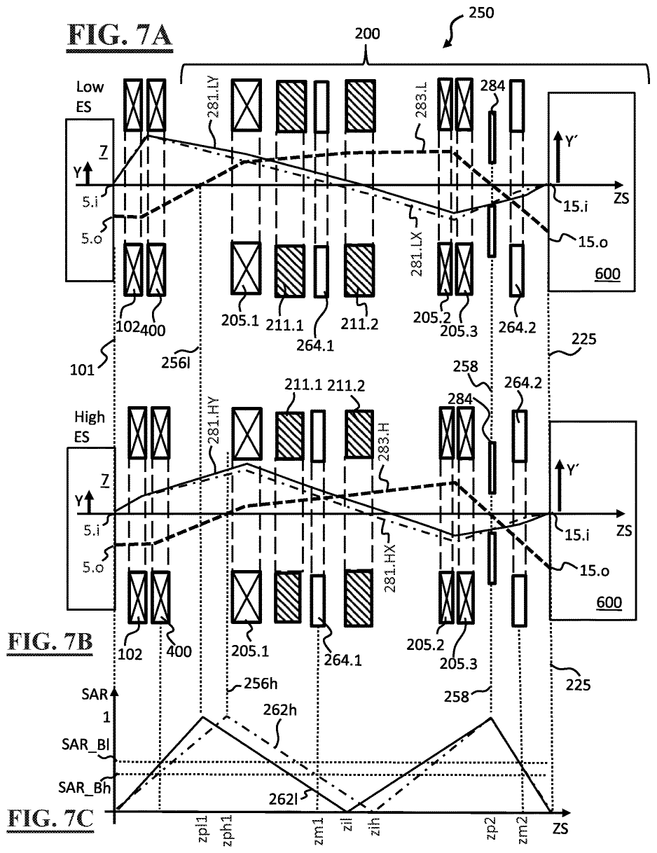

FIGS. 7A-7C illustrate a third embodiment. Same reference numbers of FIGS. 4A-4B, 5A-5C and 6A-6C are used, and reference is also made to the description of FIGS. 4 to 6. FIG. 7A illustrates selected secondary electron trajectories 281 and 283 of the improved secondary electron imaging system 250 at a first, low kinetic energy ES1 of secondary electrons. FIG. 7B illustrates selected secondary electron trajectories 281 and 283 of the improved secondary electron imaging system 250 at a second, high kinetic energy ES2 of secondary electrons. FIG. 7C illustrates the sub-aperture ratios SAR of the improved secondary electron imaging system 250 for the two selected kinetic energies ES1 and ES2 at the different zs-coordinates. According to the example of the third embodiment, the second stigmator 264.2 is positioned downstream of the aperture filter 284 at coordinate zm2>zp2. According to the example shown in figured 7A-7C, the first stigmator 264.1 is arranged upstream of the aperture stop 284. For example, the first stigmator 264.1 is arranged between a first pupil plane 256 and an intermediate image plane at position zil or zih (reference numbers 252 and 254, see FIGS. 5A-5C). Thereby, with the first stigmator 264.1, a pupil aberration is compensated, and with the second stigmator 264.2, a residual axial astigmatism and field anamorphism is compensated. In an example, the second stigmator 264.2 is positioned at a zs-coordinate zms>zp2 with a SAR similar to SAR_B of a component of the beam divider 400 for a selected kinetic energy of secondary electrons.

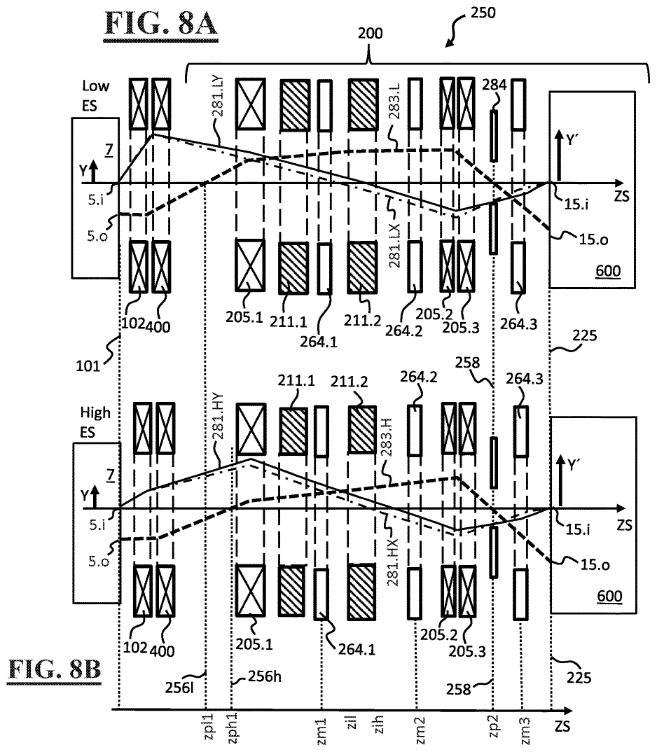

FIGS. 8A-8B illustrates a further example according to the third embodiment. Same reference numbers of FIGS. 4A-7C are used, and reference is also made to the description of FIGS. 4A-7C. FIG. 8A illustrates selected secondary electron trajectories 281 and 283 of the improved secondary electron imaging system 250 at a first, low kinetic energy ES1 of secondary electrons. FIG. 8b illustrates selected secondary electron trajectories 281 and 283 of the improved secondary electron imaging system 250 at a second, high kinetic energy ES2 of secondary electrons. In the example of FIGS. 8A-8B, the secondary electron imaging system 250 further comprises a third stigmator 264.3, with at least on stigmator 264.3 arranged downstream of an aperture filter 284. With at least three independent compensators or stigmators 264.1 to 264.3, a compensation of axial astigmatism, field anamorphism and a pupil aberration can be even more improved. In an example, at least one of the compensators 264.1 to 264.3 is positioned at a position with similar SAR compared to the SAR of the element responsible for the aberrations. In an example, at least two of the compensators 264.1 to 264.3 are positioned at a positions zm1, zm2 or zm2 with similar SAR compared to the SAR of the element responsible for the aberrations. In an example, all three compensators 264.1 to 264.3 are positioned at the positions zm1, zm2 and zm3 with similar SAR compared to the SAR of the element responsible for the aberrations. For example, the first stigmator 264.1 is arranged between a first pupil plane 256 and an intermediate image plane at position zil or zih (reference numbers 252 and 254, see FIGS. 5A-5C). The second stigmator 264.2 is arranged between the intermediate image plane (252, 254, see FIGS. 5A-5C) and the second pupil plane 258.

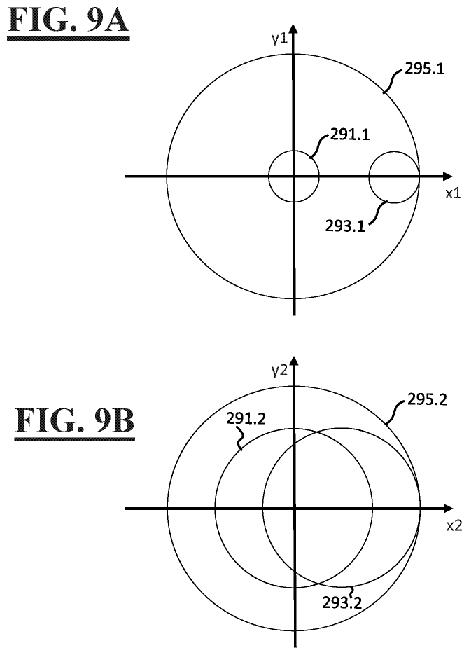

FIGS. 9A-9B illustrates the determination of the sub-aperture ratio SAR at two examples of zs-positions. FIG. 9A illustrates an example of a small SAR with small effective diameters 291.1 of an axial beamlet, close to a field plane. The bundle diameter 295.1 of the plurality of secondary electron beamlets 9 is determined by the maximum distance to the axis of an effective diameter of a secondary electron beamlet 293.1 at a peripheral field point 5.o. With small SAR, beamlets 291.1 and 293.1 may not overlap. FIG. 9B illustrates an example with a larger SAR, close to a pupil plane, where beamlets 291.2 and 293.2 overlap which each other. The effective diameter 291 or 293 of a secondary electron beamlet is defined by the filter stop 284, which may be positioned downstream of the respective zs-position.

FIG. 10 illustrates a further example according to one of the embodiments. Same reference number are used as in FIGS. 1, 2, and 4A-8b, and reference is also made to the description of FIGS. 1,2 and 4A-8c. The multi-beam charged particle beam system 1 further comprises a beam tube 151, comprising several beam tube segments 151.1 to 151.5. The beam divider 400 comprises a first beam divider segment 400.1 arranged in the primary beam path 11, and third beam divider segment 400.3 arranged in the secondary electron beam path 13, and a second beam divider segment 400.2 arranged in both primary and secondary electron beam path 11 and 13 and configured for dividing secondary electron beamlets 9 from the primary charged particles. The detection unit 200 comprises first to third electron optical lenses 205.1 to 205.3, deflection scanner 222, first and second electro-optical lens elements 211.1 and 211.2, first compensator 220, and four stigmators 264.1 to 264.4. A pupil or aperture stop 284 is arranged within a common pupil plane 258 between two tube segments 151.4 and 151.5 and for example mounted on a stage for adjustment or exchange. In the example of FIG. 10, the first and the second stigmators 264.1 and 264.2 are arranged upstream of the pupil plane 258, and the third and the fourth stigmators 264.3 and 264.4 are arranged downstream of the pupil plane 258. Thereby, axial astigmatism, field anamorphism and pupil aberrations can be individually compensated, and residual aberrations of higher order can be minimized.

The detection unit 200 further comprises the image sensor 600, which is connected to imaging control module 810, configured to receive image data during scanning operation. The first to third electron optical lenses 205.1 to 205.3, the deflection scanner 222, the first and second electro-optical lens elements 211.1 and 211.2, the first compensator 220, and the four stigmators 264.1 to 264.4 are connected to secondary beam-path control module 840. During use, secondary beam-path control module 840 is configured to provide individual control signals to first to third electron optical lenses 205.1 to 205.3, the deflection scanner 222, the first and second electro-optical lens elements 211.1 and 211.2, Secondary beam-path control module 840 is configured to generate and provide the individual control signals to the first to third electron-optical lenses in order to maintain the position of the image plane 225 and a field rotation over a large range of kinetic energies ES. Thereby, an assignment of individual detectors, for example detectors 623, to individual secondary electron beamlets 9 is maintained over a large range of kinetic energies ES. Secondary beam-path control module 840 is configured to generate and provide the individual control signals in order to maintain the position of the common pupil plane 258. Thereby, a field-invariant filter operation by aperture filter 284 is enabled over a large range of kinetic energies ES. Secondary beam-path control module 840 is further configured to generate and provide the individual control signals to the first and second stigmators 264.1 and 264.2 in order to minimize a pupil aberration within the common pupil plane 258 over a large range of kinetic energies ES. Thereby, for example an isotropic and field-invariant filter operation by aperture filter 284 is enabled over a large range of kinetic energies ES. Secondary beam-path control module 840 is further configured to generate and provide the individual control signals to the third and fourth stigmators 264.2 and 264.3. Thereby, a field aberration such as axial astigmatism of field anamorphism is minimized within the image plane 225 over a large range of kinetic energies ES.

In the example of FIG. 10, at least one of the first or second electro-optical lens elements 211.1 or 211.2 is configured as fast electrostatic lens element. Such fast lens elements are disclosed in German patent application DE 102022213751.5, filed on Dec. 16, 2022, which is hereby incorporated here within by reference. With fast lens element 211.1 or 211.2, fast changes of a kinetic energy of secondary electrons due to charging effects of the sample 7 can be compensated during an image scanning operation. A change of a kinetic energy of secondary electrons due to charging effects of the sample 7 also changes an aberration of the plurality of secondary electron beamlets 9, such as an axial astigmatism, a field anamorphism, or a pupil aberration. By configuring compensators or stigmators 264 as electrostatic element comprising a plurality of electrodes, for example eight, ten, twelve or more electrodes, a compensation of an aberration of the plurality of secondary electron beamlets 9 can be performed during scanning operation, when charges at a sample 7 are accumulated and a kinetic energy of secondary electrons is changed.

An example of operating a multi-beam charged particle beam system 1 with an improved detection unit 200 is given by the fourth to sixth embodiment. In the fourth and the second embodiment, a method of calibration of a multi-beam charged particle beam system 1 and at least one stigmator 264 is provided. Control sensitivities are determined and stored in a memory. In the sixth embodiment, an inspection task is performed by the multi-beam charged particle beam system 1 with the improved detection unit 200, utilizing the control sensitivities.

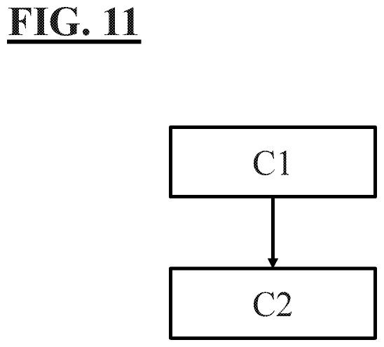

In the fourth embodiment, a method of calibration of a secondary electron imaging system is disclosed. FIG. 11 illustrates an example of the method of calibration of a secondary electron imaging system.

In step C1, an imaging or pupil aberration is determined for each of a sequence of landing energies LE(q). During the determination, for example the monitoring system 230 is used.

During step C1, a sequence of landing energies LE(q) of primary charged particles is determined. Each landing energy LE(q) with q=1 . . . . Q of primary charged particles corresponds to a specific kinetic energy ES(q) of secondary electrons and is adjusted for example by sample voltage VL. The sequence of landing energies LE(q) can be selected as a sequence of energies between 300 eV or less, for example 200 eV or 100 eV and 1 keV or more, for example 2 keV or 3 keV. The sequence can comprise Q=two, three, four or more different landing energies LE(q) with q=1 . . . to Q.

An imaging or pupil aberration is expanded into an aberration vector WR. Aberration vector WR comprises for example an axial field astigmatism or astigmatism, which is a constant astigmatism in the image plane 225, and a pupil anamorphism, describing elliptical pupil shapes in a cross-over or pupil plane 258. Further vector components can be
field anamorphism, i.e. a difference in scale in different directions in the image plane 225;
quadratic field distortion, i.e. a distortion with a quadratic dependency on field coordinate in the image plane 225; and
linear field astigmatism, i.e. an astigmatism with linear dependency of field coordinate.

Other imaging or pupil aberration of higher order are possible as well.

Each aberration vector WR therefore comprises K vector components, with K=2 or more, for example K=3, K=4, K=5, or more. For example, aberration vectors for each landing energy LE(q) are given by

WR(LE(q))=[wr1,wr2;LE(q)] (1)

with wr1 representing the axial astigmatism and wr2 representing the pupil anamorphism for landing energy LE(q).

In step C2, aberrations vectors WR (LE(q)) for the sequence of landing energies are written to a memory 890 for later use.

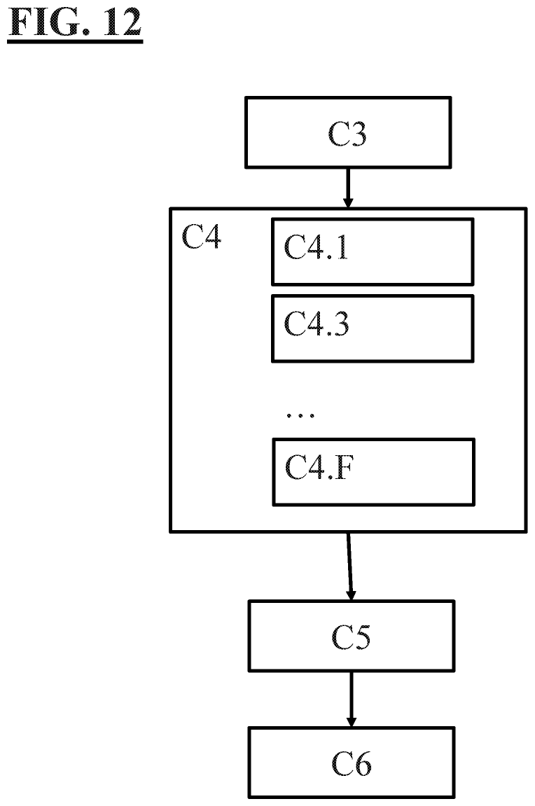

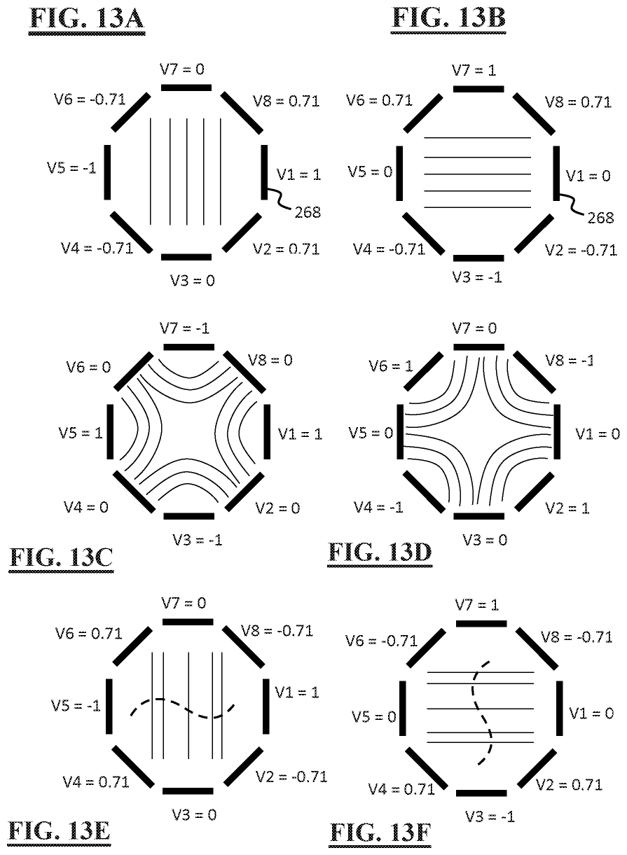

In a fifth embodiment, a method of calibration of at least one stigmator 264 is provided. An example of the calibration method is illustrated in FIG. 12. The method comprises step C3 of selecting a set of normalized actuations or modes of a stigmator 264. An example of a set of normalized actuations or modes of a stigmator 264 is illustrated in FIGS. 13A-13F at the example of a stigmator comprising eight electrodes 268. FIGS. 13A-13F illustrates N=6 modes according to orthonormal expansion similar to low order Zernike polynomials representing tilt (Z2 and Z3 for FIGS. 13A and 13B), saddle-shape (sometimes referred to as astigmatism Z5 and Z6 in FIGS. 13C and 13D) and third order waviness (sometimes referred to as coma Z7 and Z8 in FIGS. 13E and 13D). Each normalized actuation or mode M(n) is given by a vector of eight specific voltages for each of the electrodes 268 with

M(n)=[V1,V2,V3,V4,V5,V6,V7,V8]. (2)

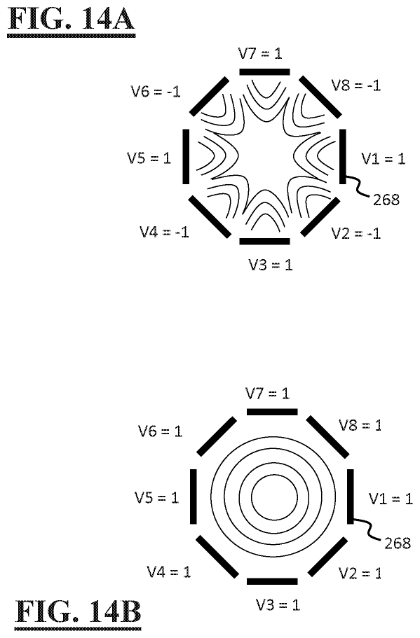

The modes are however not limited to the N=six modes according to FIGS. 13A-13F. FIG. 14A illustrates a higher order field distribution of a stigmator comprising eight electrodes 268 corresponding to higher order astigmatism. In connection with further electrodes upstream and downstream of a stigmator 264, also a low order mode of rotational symmetry corresponding to defocus or Z4 can be realized (FIG. 14B). Further and higher modes are possible with stigmators with other numbers of electrodes, for example with six, ten, twelve or more electrodes.

In step C4, each of the normalized modes M(n) with n=1 . . . . Nis applied during use to a selected stigmator 264. A change of an imaging or pupil aberration dW of a secondary electron imaging system 250 is determined for each mode M(n) and each landing energy LE(q) of the sequence of landing energies. During the determination, for example the monitoring system 230 is applied. Each change of an imaging or pupil aberration is expanded into an aberration vector dW, comprising the same vector components as aberrations vectors WR (LE(q)) utilized in step C1, for example axial field astigmatism wr1 and pupil anamorphism wr2. For each normalized mode M(n), a sensitivity S with respect to a change of a vector component if an imaging or pupil aberration dw(k;LE(q)) at the specific landing energy LE(q) is generally determined with

S(k,n;LE(q))=dw(k;LE(q))/C(n), (3)

where C(n) is the amplitude, by which actuation mode M(n) is applied to a stigmator 264. For simplification, normalized actuation modes M(n) with C(n)=1 are used.

Thereby, a sensitivity matrix S of dimension (K;N) is determined for each landing energy LE(q). Each component of sensitivity matrix S describes an excitation of vector component dw(k) by application of a normalized actuation mode M(n) to a stigmator 264.

In an example, Step C4 is repeated within sub-steps C4.1 to C4.F for each stigmator 264.1, 264.2, 264.3, 264.4. For each stigmator 264.f with index f=1 . . . . F, a sensitivity S is derived for each landing energy LE(q) with

S(k,n;LE(q);f)=dw(k;LE(q)). (4)

It is to be noted that typically the response or sensitivity S(k,n; LE(q); f) of a stigmator 264.f with respect to an actuation mode M(n) depends on the landing energy LE and thus the kinetic energy of secondary electrons. A sensitivity of a stigmator 264.f with respect to selected aberration vector components dw(k) depends on the sub-aperture ratio SAR described above. For example, with an SAR=1, no changes to a pupil anamorphism can be generated. For example, with SAR=0, no field aberration can be generated.

In optional step C5, a linearity cross-check is performed. Within the linearity range, the sensitivity S(k,n; LE(q); f) should be linear for a linear combination of actuation modes M(n) applied to different stigmators 264.f and should result in a linear combination of an aberration vector W for each landing energy:

Σ_{n,f}c(n;f)*M(n)−>W(k;LE(q))=Σ_{n,f}c(n;f)*S(k,n;LE(q);f)+errIn an (5)

example, in optional step C5, the linearity range cl(n; f) of coefficients c(n; f) is determined for each mode M(n) applied to a stigmator 264.f. A linearity range cl(n; f) is determined as maximum values of coefficients c(n; f) with deviation err below a threshold, for example err<50% of a desired property or even less, for example err<30% of a desired property.

In step c6, the sensitivity matrices S(LE(q); f) for each stigmator 264.f and for each landing energy LE(q) of the sequence of landing energies and the optionally determined constraints cl(n; f) are written to a memory 890 of the multi-beam charged particle beam system 1 for later use.

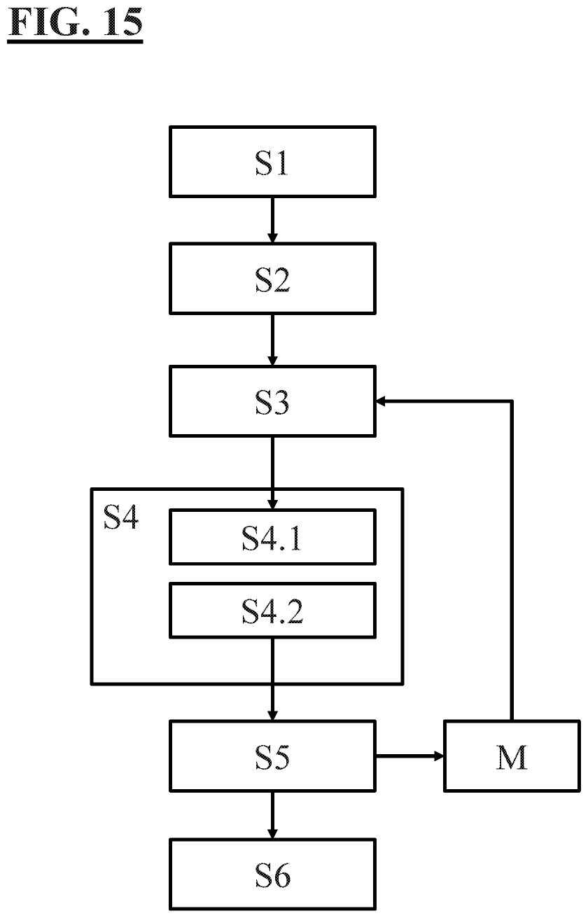

In a sixth embodiment, a method of operation of a multi-beam charged particle beam system 1 is described. An example is illustrated in FIG. 15. In step S1, an inspection task is received for example from an instruction file or a use input. An inspection site on a wafer 7 is positioned by stage 500 within the field of view of the multi-beam charged particle beam system 1. A setup of the inspection task is selected, including a selection of a landing energy LES of primary charged particles.

In step S2, a sensitivity matrix S (LES; f=1 . . . . F) of at least a first stigmator 264.1, 264.2, 264.3 or 264.4 for the selected landing energy LES is determined. For example, sensitivity matrix S (LES; f=1) for the landing energy LES is determined from a set of previously determined sensitivity matrices S̅ (LE(q); f=1) received from memory 890. In an example, a sensitivity matrix S̅(LE(q1); f=1) is selected from the sequence of landing energies with minimum difference of LE(q1) to LES. In another example, sensitivity matrix S(LES; f) is interpolated from previously determined sensitivity matrices S(LE(q); f) of at least two different landing energies LE(q) used during a calibration. Generally, during step S2, the sensitivity matrices S(LES,f) for a plurality of compensators or stigmators 264.1, 264.2, 264.3 or 264.4 is determined from previously determined sensitivity matrices S(LE(q)), which are received from memory 890. Previously determined sensitivity matrices S(LE(q),f) can for example be determined at a sequence of landing energies LE(q=1 . . . . Q) during a calibration according to the fifth embodiment. For example, each sensitivity matrix S(LES,f) at the selected landing energy LES is determined from at least two sensitivity matrices S(LE(q),f) at different landing energies LE(q) by interpolation.

In step S3, an aberration of the secondary electron imaging system 250 at the selected landing energy LES is determined. The aberration is described by an aberration vector WR with vector components according to aberration vector WR used in steps C1 or change vector dW used in C4. In an example, the aberration vector WR(LES) comprises the vector components of axial astigmatism wr1 and pupil anamorphism wr2. In an example, the aberration vector WR(LES) is determined by interpolation from at least two previously determined aberration vectors WR(LE(q)) received from memory 890. In an example, the aberration vector WR(LES) at the selected landing energy is determined during an inspection task by use of a monitoring system 230.

In step S4, an actuation of at least one stigmator 264 is determined according to linear system theory. In an example, an actuation of F stigmators 264.1 to 264.F is determined. For each stigmator 264.f=1 . . . . F, an actuation amplitude C(n;f) of a normalized actuation mode M(n) is determined. As normalized actuation modes M(n), the actuation modes selected in step C3 are applied. Actuation amplitudes C(n;f) of each mode M(n) and for each stigmator 264.f are determined by solving optimization problem of minimum aberration vector WR(LES):

∥WR(LES)−Σ_{n,f}C(n;f)*S(k,n;LES;f)∥²=min. (6)

In an example, the solution of equation (6) is based on matrix inversion. In an example, the solution of equation (6) is based on singular value decomposition (SVD).

In an example, however, the sensitivities of a pair of stigmators 264.f1 and 264.f2 with respect to an aberration vector component wr(n) can be very similar for a selected landing energy LES, such that a solution of optimization problem according to equation (6) leads to very high actuation amplitudes C(n;f1) and C(n;f2). For example, at the selected landing energy, the SAR of the two stigmators 264.f1 and 264.f2 is very similar, and both stigmators 264.f1 and 264.f2 show a similar response to an application of an actuation mode M(n). For example, at the selected landing energy, the SAR of the two stigmators 264.f1 and 264.f2 are different, and both stigmators 264.f1 and 264.f2 show a similar response to an application of a first actuation mode M(n1) to a first stigmator 264.f1 and a second actuation mode M(n2) to a second stigmator 264.f2. In such examples, the method according to the sixth embodiment comprises further constraints. In an example, the solution of equation (6) is based on a two-step approach. In a first step S4.1, the sensitivities S(k,n1; LES; f1) and sensitivities S(k,n2; LES; f2) for a pair of stigmators 264.f1 and 264.f2 are compared. If a difference in sensitivities S(k,n2; LES; f2)−S(k,n1; LES; f1) with respect to an aberration vector component w(k) is below a predetermined threshold, one actuation mode M(n1) or M(n2) of the stigmators 264.f1 or 264.f2 is discarded from the optimization problem according to eq. (6). Generally, during step S4.1, a weighting function G(n;f) is determined, by which a certain actuation mode M(n) of a selected stimator 264.f is discarded by setting weight G(n,f)=0. In a second step S4.2, the optimization problem is reduced by considering weighting function G(n;f):

∥WR(LES)−Σ_{n,f}G(n,f)*C(n,f)*S(k,n;LES;f)∥²=min. (7)

For example, at a first selected landing energy LES1, a first and a second stigmator 264.1 and 264.2 are used for compensation of an aberration WR(LES1), while a third stigmator 264.3 is not used and entirely discarded by weighting function G(n,f=3)=0. For example, at a second selected landing energy LES2, the second and a third stigmator 264.2 and 264.3 are used for compensation of an aberration WR(LES2), while the first stigmator 264.1 is not used and entirely discarded by weighting function G(f=1)=0.

Further constraints can be applied during the optimization of equation (7), for example, a voltage range applied to electrodes 268 of a stigmator 264.f can be limited, or a linearity range cl(n,f) can be limited. A linearity range cl(n,f) can be determined according to step C5 of the fifth embodiment, or a previously determined linearity range cl(n,f) can be received from memory 890.

As a result, coefficients C(n,f) of actuation modes M(n) are determined by solution of equation (7).

In an example, weighted coefficients C(n,f) of actuation modes M(n) are introduced as error function into the optimization problem; thereby, large coefficients C(n,f) of actuation modes M(n) and large voltages V1 to V8 are avoided. The optimization problem can thus be written by

∥WR(LES)−Σ_{n,f}G(n;f)*C(n;f)*S(k,n;LES;f)∥²+|T(n;f)*C(n;f)∥²−>min. (8)

With the second weight function T(n;f), linearity range cl(n,f) can be addressed. With the additional term T(nf) multiplied by the coefficients C(n,f) of actuation modes M(n), a regularization according to Tychonov is achieved. As a result, minimal coefficients C(n,f) of actuation modes M(n) are determined by solution of equation (8). In an example of equation (8), the first weighting functions G(n,f) are all set equal to G(n,f)=1.

In step S5, the resulting coefficients C(n,f) of actuation modes M(n) are applied to the respective stigmators 264.f and an inspection task is performed.

Optional step M can be performed parallel to step S5. In step M, an image of pupil aberration is determined, for example by monitoring system 230. With the actual image or pupil aberration, step S3 and step S4 are repeated during performance of an image task, and the coefficients C(n,f) of actuation modes M(n) are iteratively optimized during an inspection task. Thereby, for example drifts of the multi-beam charged particle beam system 1 or a varying surface charge during an inspection task is considered.

In step S6, the inspection result is written to memory and further processed according to the inspection task. Together with the inspection result, optionally optimized coefficients C(n,f) of actuation modes M(n) are analyzed and stored in memory 890 for later use, for example for the execution of similar inspection tasks at similar inspection positions.

A multi-beam charged particle beam system 1 comprises a memory 890 and a control operation processor 880, wherein the memory 890 is configured for storing software instructions when executed by control operation processor 880 to cause the multi-beam charged particle beam system 1 to perform at least one of the methods according to the fourth to sixth embodiment.

The disclosure can for example be described by following clauses:

Clause 1. A multi-beam charged particle beam system (1) comprising
an object irradiation unit (100), configured to form a plurality of focus points (5) of a plurality of primary charged-particle beamlets (3) in an object plane (101),
a sample stage (500), configured to arrange a surface (25) of an object (7) in the object plane (101),
a voltage supply unit (503) for providing a voltage VS to the sample (7) configured for setting a first landing energy LE1 of primary charged particles of the plurality of primary charged-particle beamlets (3),
a detection unit (200) forming at least a part of a secondary electron imaging system (250) for imaging a plurality of secondary electron beamlets (9), which are excited at the surface (25) of the object (7) at the plurality of focus points (5), along a secondary electron beam path (13) onto a detector (600),
a beam divider (400) for separating the plurality of primary charged-particle beamlets (3) from the plurality of secondary electron beamlets (9),
a first electron-optical element, arranged within the secondary electron imaging system (250) at a first position with a first ratio SAR1 of a beam diameter (293) of a single secondary electron beamlet (9) relative to the diameter (295) of the plurality of secondary electron beamlets (9) at the first landing energy LE1,
a first compensator (264.1, 264.2, 264.3) of aberrations introduced by the first electron-optical element, wherein the first compensator (264.1, 264.2, 264.3) is arranged within the secondary electron imaging system (250) at a second position with a second ratio SAR2 at the first landing energy LE1, wherein the second ratio SAR2 is identical to the first ratio SAR1 or deviating from the first ratio SAR1 by not more than 0.1.

Clause 2. The multi-beam charged particle beam system (1) according to clause 1, wherein the first electron-optical element is at least a part of the beam divider (400, 400.2, 400.3).

Clause 3. The multi-beam charged particle beam system (1) according to clause 1 or 2, wherein the first compensator (264.1, 264.2, 264.3) is a multi-pole element or stigmator.

Clause 4. The multi-beam charged particle beam system (1) according to any of the clauses 1 to 3, wherein the detection unit (200) further comprises an aperture stop (284) arranged at a pupil plane (258) of the secondary electron beam path (13) at the first landing energy LE1.

Clause 5. The multi-beam charged particle beam system (1) according to any of the clauses 1 to 4, further comprising a second compensator (264.2, 264.3, 264.4) of aberrations. Clause 6. The multi-beam charged particle beam system (1) according to clause 5, wherein the second compensator (264.1, 264.2, 264.3) is arranged within the secondary electron imaging system (250) at a third position with a third ratio SAR3 at the first landing energy LE1, wherein the third ratio SAR3 is different to the second ratio SAR2.Clause 7. The multi-beam charged particle beam system (1) according to clause 5 or 6, wherein the first compensator (264.1, 264.2, or 264.3) and the second compensator (264.2, 264.3, or 264.4) are configured to jointly compensate an aberration of the first electron-optical element at the first landing energy LE1. Clause 8. The multi-beam charged particle beam system (1) according to any of the clauses 5 to 7, wherein first compensator (264.1, 264.2, or 264.3) and the second compensator (264.2, 264.3, or 264.4) are configured to jointly compensate an aberration of the first electron-optical element at a second landing energy LE2 or primary charged particles, different from the first landing energy LE1. Clause 9. The multi-beam charged particle beam system (1) according to any of the clauses 5 to 8, wherein the secondary electron beam path (13) within the secondary electron imaging system (250) further comprises an intermediate image plane (252, 254) at the first landing energy LE1, and wherein the first compensator (264.1, 264.2, 264.3) is arranged—with respect to a propagation direction of secondary electrons—upstream of an intermediate image plane (252, 254) and the second compensator (264.2, 264.3, 264.4) is arranged downstream of the intermediate image plane (252, 254). Clause 10. The multi-beam charged particle beam system (1) according to any of the clauses 5 to 8, wherein the first compensator (264.1, 264.2, 264.3) is arranged—with respect to a propagation direction of secondary electrons—upstream of the aperture stop (284) and the second compensator (264.2, 264.3, 264.4) is arranged downstream of the aperture stop (284).Clause 11. The multi-beam charged particle beam system (1) according to any of the clauses 4 to 10, further comprising at least one correction lens (211.1, 211.2) configured to adjust the pupil plane (258) at a position of the aperture stop (284) at a second landing energy LE2 different from the first landing energy LE1.Clause 12. A multi-beam charged particle beam system (1), comprising—an object irradiation unit (100), configured to form a plurality of focus points (5) of a plurality of primary charged-particle beamlets (3) in an object plane (101),—a sample stage (500), configured to arrange a surface (25) of an object (7) in the object plane (101),—a voltage supply unit (503) for providing a voltage VS to the sample (7) configured for adjusting a landing energy LE of primary charged particles of the plurality of primary charged-particle beamlets (3) within a range between 100 eV or less and 2 keV or more,—a detection unit (200) forming at least a part of a secondary electron imaging system (250) for imaging a plurality of secondary electron beamlets (9), which are excited at the surface (25) of the object (7) at the plurality of focus points (5), along a secondary electron beam path (13) onto a detector (600),—a beam divider (400) for separating the plurality of primary charged-particle beamlets (3) from the plurality of secondary electron beamlets (9),—a first compensator (264.1, 264.2 or 264.3) and a second compensator (264.2, 264.3 or 264.4) configured to jointly compensate an aberration of an electron-optical element of the secondary electron imaging system (250) within a range of kinetic energies of secondary electrons of the plurality of secondary electron beamlets (9), corresponding to the range of the landing energy LE of the primary charged particles. Clause 13. The multi-beam charged particle beam system (1) according to clause 12, further comprising an aperture stop (284) and at least one correction lens (211.1, 211.2) configured to adjust a pupil plane (256, 258) at a position of the aperture stop (284) within the range of landing energies LE of primary charged particles beamlets (3). Clause 14. The multi-beam charged particle beam system (1) according to clause 12 or 13, wherein the secondary electron beam path (13) comprises at a first landing energy LE of primary charged particles in this order a first pupil plane (2561, 256h), an intermediate image plane (252, 254) and a second pupil plane (2581, 258h, 258). Clause 15. The multi-beam charged particle beam system (1) according to clause 14, wherein the first compensator (264.1, 264.2 or 264.3) is arranged in the secondary electron beam path (13) between the first pupil plane (2561, 256h) and the intermediate image plane (252, 254) and the second compensator (264.2, 264.3 or 264.4) is arranged in the secondary electron beam path (13) between the intermediate image plane (252, 254) and the second pupil plane (2581, 258h, 258). Clause 16. The multi-beam charged particle beam system (1) according to 15, further comprising a third compensator (264.3 or 264.4).

Clause 17. The multi-beam charged particle beam system (1) according to 16, wherein the third compensator (264.3 or 264.4) is arranged between the second pupil plane (2581, 258h, 258) and an image plane (225) of the secondary electron imaging system (250). Clause 18. The multi-beam charged particle beam system (1) according to clause 14, wherein the first compensator (264.1, 264.2 or 264.3) is arranged in the secondary electron beam path (13) between the first pupil plane (2561, 256h) and the second pupil plane (258l, 258h, 258) and the second compensator (264.2, 264.3 or 264.4) is arranged in the secondary electron beam path (13) between the second pupil plane (2581, 258h, 258) and an image plane (225) of the secondary electron imaging system (250).

Clause 19. The multi-beam charged particle beam system (1) according to any of the clauses 12 to 18, further comprising—a first electron-optical element, arranged within the secondary electron imaging system (250) at a first position with a first ratio SAR1 of a beam diameter (291) of a single secondary electron beamlet (9) relative to the diameter (293) of the plurality of secondary electron beamlets (9) at a first landing energy LE1, and wherein at least one of the first compensator (264.1, 264.2, 264.3) and the second compensator (264.2, 264.3, 264.4) is arranged within the secondary electron imaging system (250) at a second position with a second ratio SAR2 at the first landing energy LE1, wherein the second ratio SAR2 is identical to the first ratio SAR1 or deviating from the first ratio SAR1 by not more than 0.1.Clause 20. The multi-beam charged particle beam system (1) according to any of the clauses 12 to 19, wherein at least one of the compensators (264.1 to 264.4) is a multi-pole element or stigmator.

Clause 21. A method of operating a multi-beam charged particle beam system (1), comprising
positioning an inspection site on a wafer (7) by a wafer stage (500) in the field of view of a multi-beam charged particle beam system (1),
adjusting a selected landing energy LES of primary electrons within a range of landing energies by a providing a sample voltage VS to the wafer (7) by a voltage supply unit (503),
determining at least a first sensitivity matrix S(LES; 1) of the at least first compensator (264.1, 264.2, 264.3, 264.4) for the selected landing energy LES,
determining an aberration of a secondary electron imaging system (250) at the selected landing energy LES,
determining a first actuation of the at least first compensator (264.1, 264.2, 264.3, 264.4) at the selected landing energy LES for compensating the aberration,
applying the first actuation of the at least first compensator (264.1, 264.2, 264.3, 264.4) and performing the inspection task.

Clause 22. The method according to clause 21, wherein determining the aberration comprises describing the aberration by an aberration vector WR(LES) comprising at least two preselected aberration vector components selected from a group of normalized aberration vector components including axial astigmatism, pupil anamorphism, field anamorphism, quadratic field distortion, linear field astigmatism.

Clause 23. The method according to any of the clauses 21 to 22, further comprising determining a second sensitivity matrix S(LES; f=2) of a second compensator (264.2, 264.3, 264.4) for the selected landing energy LES and determining a second actuation of the second compensator (264.2, 264.3, 264.4) at the selected landing energy LES. Clause 24. The method according to clause 23, wherein determining the first actuation and the second actuation of the at least first and second compensators (264.1, 264.2, 264.3, 264.4) comprises determining at least one actuation amplitude C(n,f) of a plurality of normalized actuation modes M(n) for each compensator (264.1, 264.2, 264.3, 264.4). Clause 25. The method according to clause 24, wherein the determining the first actuation and the second actuation of the at least first and second compensators (264.1, 264.2, 264.3, 264.4) comprises performing an optimization of a matrix equation

∥WR(LES)−Σ_{n,f}G(n;f)*C(n;f)*S(k,n;LES;f)∥²−>min
with aberration vector WR(LES),
actuation amplitude C(n,f) of the plurality of normalized actuation modes M(n) for each compensator with f=1 . . . F (264.1, 264.2, 264.3, 264.4),
sensitivity matrices S(LES; f) for each compensator (264.1, 264.2, 264.3, 264.4), and a set of predetermined first weighting functions G(n,f).

Clause 26. The method according to clause 24, wherein the determining the first actuation and the second actuation of the at least first and second compensators (264.1, 264.2, 264.3, 264.4) comprises performing an optimization of a matrix equation including a minimization of actuation amplitudes C(n,f) of the plurality of normalized actuation modes M(n) for each compensator (264.1, 264.2, 264.3, 264.4).

Clause 27. The method according to clause 26, wherein the optimization of the matrix equation is written as

∥WR(LES)−Σ_{n,f}G(n,f)*C(n,f)*S(k,n;LES;f)∥²+|T(n;f)*C(n;f)∥²−>min
with aberration vector WR(LES),
actuation amplitude C(n,f) of the plurality of normalized actuation modes M(n) for each compensator (264.1, 264.2, 264.3, 264.4),
sensitivity matrices S(LES; f) for each compensator (264.1, 264.2, 264.3, 264.4), a set of predetermined first weighting functions G(n,f),
and a second set of predetermined second weighting functions (T(n,f). Clause 28. The method according to any of the clauses 24 to 27, wherein the first weighting function G(n,f) is set to a value G(n,f)>1 for a first compensator (264.1, 264.2 or 264.3) for a first selected landing energy LES1 and is set to G(n,f)=0 for a second landing energy LES2.Clause 29. The method according to any of the clauses 21 to 28, wherein determining a sensitivity matrix S(LES; f) of a compensator (264.1, 264.2, 264.3 or 264.4) comprises determining the sensitivity matrix S(LES; f) from a set of previously determined sensitivity matrices S (LE(q); f=1) received from a memory (890). Clause 30. The method according to any of the clauses 21 to 29, wherein a sensitivity matrix S(LES; f) of a compensator (264.1, 264.2, 264.3 or 264.4) is interpolated from previously determined sensitivity matrices S(LE(q); f) at at least two different landing energies LE(q1) and LE(q2) by interpolation. Clause 31. The method according to any of the clauses 21 to 30, further comprising determining the aberration of the secondary electron imaging system (250) at the selected landing energy LES by using a monitoring system (230).Clause 32. The method according to any of the clauses 21 to 30, comprising determining the aberration of the secondary electron imaging system (250) at the selected landing energy LES from at least two previously determined aberration vectors WR(Le(q)) received from a memory (890). Clause 33. A method of calibrating of at least one compensator (264) of a secondary electron imaging system (250) of a multi-beam charged particle beam system (1) within a range of landing energies LE, comprising-determining a set of N normalized actuation modes M(n) of the compensator (264),—determining an aberration vector W of the secondary electron imaging system (250), the aberration vector WR comprising at least K=2 normalized aberration vector components selected from a group of normalized aberration vector components including axial astigmatism, pupil anamorphism, field anamorphism, quadratic field distortion, linear field astigmatism,—individually applying each normalized actuation mode M(n) with an actuation amplitude C(n) at the compensator (264),—adjusting a first landing energy LE(1) from a set of landing energies LE(q) and determining a change of an aberration vector dW at the first landing energy LE(1) induced by applying an actuation mode M(n) to the compensator (264),—repeating adjusting the landing energy and determining a change of an aberration dW for each landing energy LE(q)=(2 . . . . Q) of the set of landing energies and each normalized actuation mode M(n),—determining a sensitivity matrix S(k=1 . . . . K,n=1 . . . . N,LE(q)) of K normalized aberration vector components of each normalized actuation mode M(n=1 . . . . N) for each of the landing energies LE(q),—storing the plurality of sensitivity matrices S(k=1 . . . . K,n=1 . . . . N,LE(q)) in a memory (890). Clause 34. The method according to clause 33, further comprising determining an aberration vector WR comprising the at least K=2 normalized aberration vector components of the secondary electron imaging system (250) at each landing energy LE(q)=(2 . . . . Q) of the set of landing energies by using a monitoring system (230) without actuation of a compensator (264).Clause 35. A multi-beam charged particle beam system (1), comprising—an object irradiation unit (100), configured to form a plurality of focus points (5) of a plurality of primary charged-particle beamlets (3) in an object plane (101),—a sample stage (500), configured to arrange a surface (25) of an object (7) in the object plane (101),—a voltage supply unit (503) for providing a voltage VS to the sample (7) configured for setting a selected landing energy LES of primary charged particles of the plurality of primary charged-particle beamlets (3) within a range of landing energies LE,—a detection unit (200) forming at least a part of a secondary electron imaging system (250) for imaging a plurality of secondary electron beamlets (9), which are excited at the surface (25) of the object (7) at the plurality of focus points (5), along a secondary electron beam path (13) onto a detector (600),—a beam divider (400) for separating the plurality of primary charged-particle beamlets (3) from the plurality of secondary electron beamlets (9),—at least a first compensator (264.1, 264.2, 264.3) of aberrations arranged within the secondary electron imaging system (250),—a control unit (800) comprising control operation processor (880) and a memory (890) for storing software instructions, when executed by the control operation processor (880) causing the multi-beam charged particle beam system (1) to perform any of the methods according to clauses 21 to 34.Clause 36. The multi-beam charged particle beam system (1) according to clause 35, further comprising a second compensator (264.2, 264.3, 264.4) of aberrations arranged within the secondary electron imaging system (250). Clause 37. The multi-beam charged particle beam system (1) according to clause 36, further comprising a third compensator (264.3, 264.4) of aberrations arranged within the secondary electron imaging system (250).

The disclosure is however not limited to the embodiments or clauses described above. The clauses, embodiments or examples can be fully or partly combined with one another, and various modifications within the scope of any person of ordinary skill in the art are covered by the embodiments and examples of the disclosure.

A list of reference numbers is provided:
1 multi-beamlet charged-particle system
3 primary charged particle beamlets, or plurality of primary charged particle beamlets
5 primary charged particle beam spot
7 object or sample
9 secondary electron beamlet, forming the plurality of secondary electron beamlets
13 secondary electron beam path
15 secondary charged particle focus spot
25 surface of object or sample
67 first material composition
69 second material composition
100 object irradiation unit
101 image plane
102 objective lens
103 field lens
108 first beam cross over
110 collective multi-beam raster scanner
133 electrode
135 first electric field
137 second electric field
151 beam tube
153 Beam exit opening
161 coil
163 pole shoe
165 lower pole shoe segment
200 detection unit
205 magneto-dynamic lens
211 correction lens
220 multi-pole corrector
222 second raster scanner
225 secondary electron image plane
230 monitoring system
232 high resolution sensor
235 imaging lens
237 beam divider mirror
250 secondary electron imaging system
252 Low energy intermediate image position
254 High energy intermediate image position
256 first cross or pupil over position
258 second cross over or pupil position
262 SAR through system
264 multi-pole corrector
266 position of multi-pole corrector
268 electrode
281 electron trajectory of axial point
283 electron trajectory of field point
284 Aperture stop
291 beamlet of axial field point
293 beamlet of peripheral field point
295 footprint of plurality of beamlets
300 charged-particle multi-beamlet generator
301 charged particle source
303 collimating lenses
304 filter plate
305 primary multi-beamlet-forming unit
306 multi-aperture plates
309 primary electron beam
321 intermediate image surface
331 first field lens
333 second field lens
400 beam splitter or divider unit
500 sample stage
503 Sample voltage supply
505 sample mounting platform
600 image sensor
602 electron to photon conversion unit
605 collection lens
611 zoom lens
623 detection element
800 control unit
810 imaging control module
820 sensor module
830 primary beam-path control module
840 secondary beam-path control module
850 stage control module
860 scanning control unit
880 control operation processor
890 memory

What is claimed is:

1. A multi-beam charged particle beam system configured to generate a plurality of primary charged-particle beamlets, the multi-beam charged particle beam system comprising:
an object irradiation unit configured to generate a plurality of focus points of the plurality of primary charged-particle beamlets in an object plane of the multi-beam charged particle beam system;
a sample stage configured to arrange a surface of an object in the object plane;
a voltage supply unit configured to provide a voltage to the object to set a first landing energy of primary charged particles of the plurality of primary charged-particle beamlets;
a detection unit configured to provide at least a part of a secondary electron imaging system configured to image a plurality of secondary electron beamlets generated at the surface of the object at the plurality of focus points, the secondary electron beamlets travelling along a secondary electron beam path onto a detector of the detection unit;
a beam divider configured to separate the plurality of primary charged-particle beamlets from the plurality of secondary electron beamlets;
a first electron-optical element within the secondary electron imaging system at a first position with a first ratio of a beam diameter of a single secondary electron beamlet relative to a diameter of the plurality of secondary electron beamlets at the first landing energy;
a first compensator configured to compensate aberrations introduced by the first electron-optical element,
wherein the first compensator is within the secondary electron imaging system at a second position with a second ratio at the first landing energy, and
wherein the second ratio is the same as the first ratio, or the second ration deviates from the first ratio by at most 0.1.

2. The multi-beam charged particle beam system of claim 1, wherein the first electron-optical element is at least a part of the beam divider.

3. The multi-beam charged particle beam system of claim 1, wherein the first compensator comprises a multi-pole element or a stigmator.

4. The multi-beam charged particle beam system of claim 1, wherein the detection unit further comprises an aperture stop disposed in a pupil plane of the secondary electron beam path at the first landing energy.

5. The multi-beam charged particle beam system of claim 1, further comprising a second compensator configured to compensate aberrations.

6. The multi-beam charged particle beam system of claim 5, wherein the second compensator is within the secondary electron imaging system at a third position with a third ratio at the first landing energy, wherein the third ratio is different from the second ratio.

7. The multi-beam charged particle beam system of claim 5, wherein the first and second compensators are configured to jointly compensate an aberration of the first electron-optical element at the first landing energy.

8. The multi-beam charged particle beam system of claim 5, wherein first and second compensators are configured to jointly compensate an aberration of the first electron-optical element at a second landing energy of primary charged particles, the second landing energy being different from the first landing energy.

9. The multi-beam charged particle beam system of claim 5, wherein:
the secondary electron beam path within the secondary electron imaging system comprises an intermediate image plane at the first landing energy; and
with respect to a propagation direction of secondary electrons: the first compensator is upstream of the intermediate image plane; and the second compensator is downstream of the intermediate image plane.

10. The multi-beam charged particle beam system of claim 5, wherein:
the detection unit further comprises an aperture stop disposed in a pupil plane of the secondary electron beam path at the first landing energy; and
with respect to a propagation direction of secondary electrons: the first compensator is upstream of the aperture stop; and the second compensator is downstream of the aperture stop.

11. The multi-beam charged particle beam system of claim 4, further comprising a correction lens configured to adjust the pupil plane at a position of the aperture stop at a second landing energy different from the first landing energy.

12. A multi-beam charged particle beam system configured to generate a plurality of primary charged-particle beamlets, the multi-beam charged particle beam system comprising:
an object irradiation unit configured to generate a plurality of focus points of the plurality of primary charged-particle beamlets in an object plane of the multi-beam charged particle beam system;
a sample stage configured to arrange a surface of an object in the object plane;
a voltage supply unit configured to provide a voltage to the object to set a landing energy of primary charged particles of the plurality of primary charged-particle beamlets within a range between 100 eV or less and 2 keV or more;
a detection unit configured to provide at least a part of a secondary electron imaging system configured to image a plurality of secondary electron beamlets generated at the surface of the object at the plurality of focus points, the secondary electron beamlets travelling along a secondary electron beam path onto a detector of the detection unit;
a beam divider configured to separate the plurality of primary charged-particle beamlets from the plurality of secondary electron beamlets;
a first compensator; and
a second compensator,
wherein the first and second compensators are configured to jointly compensate an aberration of an electron-optical element of the secondary electron imaging system within a range of kinetic energies of secondary electrons of the plurality of secondary electron beamlets that is the same as the range of the landing energy of the primary charged particles.

13. The multi-beam charged particle beam system of claim 12, further comprising:
an aperture stop; and
a correction lens configured to adjust a pupil plane at a position of the aperture stop within the range of landing energies of primary charged particles beamlets.

14. The multi-beam charged particle beam system of claim 12 wherein the secondary electron beam path comprises at a first landing energy of primary charged particles in order: a first pupil plane; an intermediate image plane; and a second pupil plane.

15. The multi-beam charged particle beam system of claim 12, further comprising a first electron-optical element within the secondary electron imaging system at a first position with a first ratio of a beam diameter of a single secondary electron beamlet relative to a diameter of the plurality of secondary electron beamlets at a first landing energy,
wherein the first compensator and/or the second compensator is arranged within the secondary electron imaging system at a second position with a second ratio at the first landing energy, and
wherein the second ratio is the same as the first ratio, or the second ratio deviates from the first ratio by at most 0.1.

16. The multi-beam charged particle beam system of claim 12, wherein the first compensator comprises a multi-pole element.

17. A method of operating a multi-beam charged particle beam system, the method comprising:
positioning an inspection site on a wafer in a field of view of the multi-beam charged particle beam system;
adjusting a selected landing energy of primary electrons within a range of landing energies by providing a sample voltage to the wafer;
determining a sensitivity matrix of a compensator for the selected landing energy LES;
determining an aberration of a secondary electron imaging system at the selected landing energy;
determining an actuation of the compensator at the selected landing energy to compensate the aberration;
applying the actuation of first compensator; and
inspecting the wafer.

18. One or more machine readable hardware storage devices comprising instructions that are executable by one or more processing devices to perform the method of claim 17.

19. A system, comprising:
one or more processing devices; and
one or more machine readable hardware storage devices comprising instructions that are executable by the one or more processing devices to perform the method of claim 17.

20. The system of claim 19, further comprising:
an object irradiation unit configured to generate a plurality of focus points of the plurality of primary charged-particle beamlets on the wafer;
a voltage supply unit configured to provide the voltage to the wafer;
a detection unit that is at least a part of a secondary electron imaging system configured to image a plurality of secondary electron beamlets generated at the surface of the wafer at the plurality of focus points, the secondary electron beamlets travelling along a secondary electron beam path onto a detector of the detection unit; and
a beam divider configured to separate the plurality of primary charged-particle beamlets from the plurality of secondary electron beamlets.
